(19) United States
(12) Patent Application Publication
(10) Pub. No.: US 2022/0004729 A1
(43) Pub. Date: Jan. 6, 2022

(54) FINGERPRINT IDENTIFICATION CIRCUIT AND DRIVING METHOD THEREOF, FINGERPRINT IDENTIFICATION MODULE, AND DISPLAY DEVICE

(71) Applicant: BOE TECHNOLOGY GROUP CO., LTD., Beijing (CN)

(72) Inventors: Pengpeng WANG, Beijing (CN); Haisheng WANG, Beijing (CN); Xiaoliang DING, Beijing (CN); Yingming LIU, Beijing (CN); Liang CUI, Beijing (CN); Yubo WANG, Beijing (CN); Yangbing LI, Beijing (CN); Xiufeng LI, Beijing (CN); Xueyou CAO, Beijing (CN)

(21) Appl. No.: 16/959,220

(22) PCT Filed: Aug. 21, 2019
(86) PCT No.: PCT/CN2019/103445

§ 371 Date: Jun. 30, 2020

(51) Int. Cl. G06K 9/00; G06K 9/20; H01L 27/12; G01S 15/89

(52) U.S. Cl. CPC G06K 9/0002; G01S 15/8915; H01L 27/1214; G06K 9/209

(57) ABSTRACT

A fingerprint identification circuit and a driving method thereof, a fingerprint identification module, and a display device are provided. The fingerprint identification circuit includes a plurality of first signal receiving circuit groups, a plurality of second signal receiving circuit groups, and a plurality of first signal acquisition lines. The plurality of first signal acquisition lines are arranged in one-to-one correspondence with the plurality of first signal receiving circuit groups, and each first signal acquisition line is connected with multiple first acquisition signal input terminals of multiple signal receiving circuits in a corresponding one of the first signal receiving circuit groups.

### TECHNICAL FIELD

Embodiments of the present disclosure relates to a fingerprint identification circuit, a driving method of the fingerprint identification circuit, a fingerprint identification module, and a display device.

### BACKGROUND

With the continuous development of science and technology, fingerprint identification technology has been gradually applied to people's daily life. Fingerprint identification technology can achieve a function of identity identification by comparing the detail features of different fingerprints. Generally, the fingerprint identification technology can be divided into optical fingerprint identification technology, silicon chip fingerprint identification technology, and ultrasonic fingerprint identification technology.

At present, the ultrasonic fingerprint identification technology is a hot research direction for major manufacturers. An ultrasonic fingerprint identification structure is mainly a three-layered structure, which comprises a driving electrode, a receiving electrode, and a piezoelectric layer located between the driving electrode and the receiving electrode. Upon a driving voltage being applied to the driving electrode and the receiving electrode, the piezoelectric layer is excited by the voltage to generate an inverse piezoelectric effect and transmit a first ultrasonic wave outward. The first ultrasonic wave is reflected back to form a second ultrasonic wave by a finger after contacting the finger. Because a fingerprint includes valleys and ridges, vibration intensities of the second ultrasonic wave reflected back to the piezoelectric layer by the fingerprint are different. In this case, upon a fixed voltage being applied to the driving electrode, the piezoelectric layer can convert the second ultrasonic wave into a voltage signal, which is transmitted to the fingerprint identification module through the receiving electrode, and positions of the valleys and ridges of the fingerprint are judged according to the voltage signal.

### SUMMARY

The embodiments of the present disclosure provide a fingerprint identification circuit, a driving method of the fingerprint identification circuit, a fingerprint identification module and a display device. The fingerprint identification circuit includes a plurality of signal receiving circuits arranged in an array along a first direction and a second direction to form a plurality of first signal receiving circuit groups arranged along the first direction and a plurality of second signal receiving circuit groups arranged along the second direction; and a plurality of first signal acquisition lines, each of the first signal acquisition lines extends along a second direction, the plurality of first signal acquisition lines are arranged along the first direction, each of the signal receiving circuits includes an acquisition sub-circuit and an output sub-circuit, the acquisition sub-circuit includes a first acquisition signal input terminal and a first acquisition signal output terminal, the output sub-circuit includes a first read control terminal, a first data output terminal, and a data input terminal, the first acquisition signal output terminal and the data input terminal are connected to a first node, the first node is configured to be connected with a receiving electrode of the ultrasonic sensor, the plurality of first signal acquisition lines are arranged in one-to-one correspondence with the plurality of first signal receiving circuit groups, and each of the first signal acquisition lines is connected with multiple first acquisition signal input terminals of multiple signal receiving circuits arranged along the second direction in a corresponding one of the plurality of first signal receiving circuit groups. Therefore, the fingerprint identification circuit can apply acquisition signals with different time sequences to the plurality of first signal receiving circuits through the plurality of first signal acquisition lines, thereby achieving a receiving focusing function and improving fingerprint identification performance Specifically, the fingerprint identification circuit can improve signal quantity and signal-to-noise ratio, and can also achieve read and operation at the same time, thus improving the speed and efficiency of fingerprint identification while ensuring high signal-to-noise ratio.

At least one embodiment of the present disclosure provides a fingerprint identification circuit, which includes: a plurality of signal receiving circuits, arranged in an array along a first direction and a second direction to form a plurality of first signal receiving circuit groups arranged along the first direction and extending along the second direction and a plurality of second signal receiving circuit groups arranged along the second direction and extending along the first direction; and a plurality of first signal acquisition lines, each of the first signal acquisition lines extending along the second direction, the plurality of first signal acquisition lines arranged along the first direction, each of the signal receiving circuits includes an acquisition sub-circuit and an output sub-circuit, the acquisition sub-circuit includes a first acquisition signal input terminal and a first acquisition signal output terminal, the output sub-circuit includes a first read control terminal, a first data output terminal, and a data input terminal, the first acquisition signal output terminal and the data input terminal are connected to a first node, the first node is configured to be connected with a receiving electrode of an ultrasonic sensor, the plurality of first signal acquisition lines are arranged in one-to-one correspondence with the plurality of first signal receiving circuit groups, and each of the first signal acquisition lines is connected with multiple first acquisition signal input terminals of multiple signal receiving circuits arranged along the second direction in a corresponding one of the plurality of first signal receiving circuit groups.

For example, the fingerprint identification circuit provided by an embodiment of the present disclosure further includes: a plurality of first read control lines, each of the first read control lines extending along the first direction, and the plurality of first read control lines arranged along the second direction; and a plurality of first data read lines, each of the first data read lines extending along the second direction, the plurality of first data read lines arranged along the first direction, wherein the plurality of first read control lines and the plurality of second signal receiving circuit groups are arranged in one-to-one correspondence, the plurality of first data read lines and the plurality of first signal receiving circuit groups are arranged in one-to-one correspondence, each of the first read control lines is connected with multiple first read control terminals of multiple signal receiving circuits extending along the first direction in a corresponding one of the second signal receiving circuit groups, and each of the first read control lines is connected with multiple first data output terminals of multiple signal receiving circuits extending along the second direction in a corresponding one of the first signal receiving circuit groups.

For example, the fingerprint identification circuit provided by an embodiment of the present disclosure further includes: a plurality of second signal acquisition lines, each of the second signal acquisition lines extending along the first direction, the plurality of second signal acquisition lines arranged along the second direction, the acquisition sub-circuit further includes a second acquisition signal input terminal and a second acquisition signal output terminal, the second acquisition signal output terminal is connected to the first node; the plurality of second signal acquisition lines are arranged in one-to-one correspondence with the plurality of second signal receiving circuit groups; and each of the second signal acquisition lines is connected with multiple second acquisition signal input terminals of multiple signal receiving circuits arranged along the first direction in a corresponding one of the second signal receiving circuit groups.

For example, the fingerprint identification circuit provided by an embodiment of the present disclosure further includes: a plurality of second read control lines, each of the second read control lines extending along the second direction, and the plurality of second read control lines arranged along the first direction; and a plurality of second data read lines, each of the second data read lines extending along the first direction, the plurality of second data read lines arranged along the second direction, the output sub-circuit includes a second read control terminal and a second data output terminal, the plurality of second read control lines are arranged in one-to-one correspondence with the plurality of first signal receiving circuit groups, the plurality of second data read lines are arranged in one-to-one correspondence with the plurality of second signal receiving circuit groups, each of the second read control lines is connected with multiple second read control terminals of multiple the signal receiving circuits extending along the second direction in a corresponding one of the first signal receiving circuit groups, and each of the second read control lines is connected with multiple second data output terminals of multiple signal receiving circuits extending along the first direction in a corresponding one of the second signal receiving circuit groups.

For example, in the fingerprint identification circuit provided by an embodiment of the present disclosure, the acquisition sub-circuit includes: a first diode, including a first anode and a first cathode, each of the first signal acquisition lines is connected with the first anode, the first cathode is connected to the first node, the first anode is the first acquisition signal input terminal, and the first cathode is the first acquisition signal output terminal.

For example, in the fingerprint identification circuit provided by an embodiment of the present disclosure, the acquisition sub-circuit includes: a first thin film transistor, including a first gate electrode, a first source electrode, and a first drain electrode, the fingerprint identification circuit further includes a plurality of first acquisition control lines, each of the first acquisition control lines extends along the second direction, the plurality of first acquisition control lines are arranged along the first direction, the plurality of first acquisition control lines are arranged in one-to-one correspondence with the plurality of first signal receiving circuit groups, each of the first acquisition control lines is connected with multiple first gate electrodes of multiple signal receiving circuits arranged along the second direction in a corresponding one of the first signal receiving circuit groups, the first source electrode is the first acquisition signal input terminal, and the first drain electrode is the first acquisition signal output terminal.

For example, in the fingerprint identification circuit provided by an embodiment of the present disclosure, the output sub-circuit includes: a second thin film transistor, including a second gate electrode, a second source electrode, and a second drain electrode; and a third thin film transistor, including a third gate electrode, a third source electrode, and a third drain electrode, the second gate electrode is connected to the first node, the second source electrode is configured to be connected with a high voltage source, the second drain electrode is connected to a second node, the third source electrode is connected to the second node, the second gate electrode is the data input terminal, the third gate electrode is the first read control terminal, and the third drain electrode is the first data output terminal.

For example, in the fingerprint identification circuit provided by an embodiment of the present disclosure, the acquisition sub-circuit further includes: a fourth thin film transistor, including a fourth gate electrode, a fourth source electrode, and a fourth drain electrode, the fingerprint identification circuit further includes a plurality of second acquisition control lines, each of the second acquisition control lines extends along the first direction, the plurality of second acquisition control lines are arranged along the second direction, the plurality of second acquisition control lines are arranged in one-to-one correspondence with the plurality of second signal receiving circuit groups, each of the second acquisition control lines is connected with multiple fourth gate electrodes of multiple signal receiving circuits arranged along the first direction in a corresponding one of the second signal receiving circuit groups, the fourth source electrode is the second acquisition signal input terminal, and the fourth drain electrode is the second acquisition signal output terminal.

For example, in the fingerprint identification circuit provided by an embodiment of the present disclosure, the acquisition sub-circuit further includes: a second diode, including a second anode and a second cathode, the first drain electrode and the fourth drain electrode are connected with the second anode, and the second cathode is connected to the first node.

For example, in the fingerprint identification circuit provided by an embodiment of the present disclosure, the output sub-circuit includes: a second thin film transistor, including a second gate electrode, a second source electrode, and a second drain electrode; a third thin film transistor, including a third gate electrode, a third source electrode, and a third drain electrode; and a fifth thin film transistor, including a fifth gate electrode, a fifth source electrode, and a fifth drain electrode, the second gate electrode is connected to the first node, the second source electrode is configured to be connected with a high voltage source, the second drain electrode is connected to the second node, the third source electrode is connected to the second node, the second gate electrode is the data input terminal, the third gate electrode is the first read control terminal, the third drain electrode is the first data output terminal, the fifth source electrode is connected to the second node, the fifth gate electrode is the second read control terminal, and the fifth drain electrode is the second data output terminal.

For example, in the fingerprint identification circuit provided by an embodiment of the present disclosure, each of the signal receiving circuits further includes a reset sub-circuit, the reset sub-circuit includes a sixth thin film transistor, the sixth thin film transistor includes a sixth gate electrode, a sixth source electrode, and a sixth drain electrode, the sixth gate electrode is connected with a reset control line, the sixth source electrode is connected with the reset voltage source, and the sixth drain electrode is connected to the first node.

At least one embodiment of the present disclosure further provides a fingerprint identification module, which includes any one of the abovementioned fingerprint identification circuit.

For example, the fingerprint identification module provided by an embodiment of the present disclosure further includes: a plurality of ultrasonic sensors, each of the ultrasonic sensors including a transmitting electrode, a receiving electrode, and a piezoelectric material layer located between the transmitting electrode and the receiving electrode, the plurality of ultrasonic sensors and the plurality of signal receiving circuits are arranged in one-to-one correspondence, and the first node of each of the signal receiving circuits is connected with the receiving electrode of a corresponding one of the ultrasonic sensors.

For example, in the fingerprint identification module provided by an embodiment of the present disclosure, the plurality of ultrasonic sensors are arranged in an array along the first direction and the second direction to form a plurality of first ultrasonic sensor groups arranged along the first direction and a plurality of second ultrasonic sensor groups arranged along the second direction, transmitting electrodes of multiple ultrasonic sensors arranged along the second direction in each of the first ultrasonic sensor groups are different, and multiple ultrasonic sensors arranged along the first direction in each of the second ultrasonic sensor groups share one transmitting electrode having a strip shape.

At least one embodiment of the present disclosure further provides a display device, including any one of the fingerprint identification module as described above.

At least one embodiment of the present disclosure further provides a driving method of the fingerprint identification circuit as described above, which includes: dividing the plurality of first signal acquisition lines into N first signal acquisition line groups, each of the first signal acquisition line groups including at least two first signal acquisition lines; after the ultrasonic sensor transmits an ultrasonic wave, according to an arrival time of reflected echo, the at least two first signal acquisition lines in each of the first signal acquisition line groups apply acquisition signals to multiple first acquisition signal input terminals of multiple signal receiving circuits arranged along the second direction in a corresponding one of the first signal receiving circuit groups at different time points to receive the reflected echo; and performing weighted summation on data output by multiple first data output terminals of the corresponding one of the first signal receiving circuit groups corresponding to the at least two first acquisition signal lines to obtain first fingerprint information, N is a positive integer greater than or equal to 1.

For example, in the driving method of the fingerprint identification circuit provided by an embodiment of the present disclosure, the fingerprint identification circuit further includes: a plurality of first read control lines, each of the first read control lines extending along the first direction, and the plurality of first read control lines arranged along the second direction; and a plurality of first data read lines, each of the first data read lines extending along the second direction, the plurality of first data read lines arranged along the first direction, the plurality of first read control lines and the plurality of second signal receiving circuit groups are arranged in one-to-one correspondence, the plurality of first data read lines and the plurality of first signal receiving circuit groups are arranged in one-to-one correspondence, each of the first read control lines is connected with multiple first read control terminals of multiple signal receiving circuits extending along the first direction in a corresponding one of the second signal receiving circuit groups, and each of the first read control lines is connected with multiple first data output terminals of multiple signal receiving circuits extending along the second direction in a corresponding one of the first signal receiving circuit groups, and the driving method further includes: after the plurality of first signal acquisition lines send the acquisition signals, applying turn-on signals to the multiple first read control terminals of the multiple signal receiving circuits extending along the first direction in the corresponding one of the second signal receiving circuit groups through the plurality of first read control lines respectively.

For example, in the driving method of the fingerprint identification circuit provided by an embodiment of the present disclosure, the fingerprint identification driving circuit further includes a plurality of second signal acquisition lines, each of the second signal acquisition lines extending along the first direction, the plurality of second signal acquisition lines arranged along the second direction, the acquisition sub-circuit further includes a second acquisition signal input terminal and a second acquisition signal output terminal, the second acquisition signal output terminal is connected to the first node; the plurality of second signal acquisition lines are arranged in one-to-one correspondence with the plurality of second signal receiving circuit groups; and each of the second signal acquisition lines is connected with multiple second acquisition signal input terminals of multiple signal receiving circuits arranged along the first direction in a corresponding one of the second signal receiving circuit groups, the driving method further includes: dividing the plurality of second signal acquisition lines into M second signal acquisition line groups, each of the second signal acquisition line groups includes at least two second signal acquisition lines; after the ultrasonic sensor transmits an ultrasonic wave, according to an arrival time of reflected echo, the at least two second signal acquisition lines in each of the second signal acquisition line groups apply acquisition signals to the multiple second acquisition signal input terminals of the multiple of signal receiving circuits arranged along the first direction in the corresponding one of the second signal receiving circuit groups at different time points to receive the reflected echo; and performing weighted summation on data output by the multiple second data output terminals of the corresponding one of the second signal receiving circuit groups corresponding to the at least two second acquisition signal lines to obtain second fingerprint information, M is a positive integer greater than or equal to 1.

For example, the driving method of the fingerprint identification circuit provided by an embodiment of the present disclosure further includes: processing the first fingerprint information and the second fingerprint information to obtain third fingerprint information.

For example, in the driving method of the fingerprint identification circuit provided by an embodiment of the present disclosure, the fingerprint identification circuit further includes a plurality of second read control lines and a plurality of second data read lines, each of the second read control lines extending along the second direction, and the plurality of second read control lines arranged along the first direction; each of the second data read lines extending along the first direction, the plurality of second data read lines arranged along the second direction, the output sub-circuit includes a second read control terminal and a second data output terminal, the plurality of second read control lines are arranged in one-to-one correspondence with the plurality of first signal receiving circuit groups, the plurality of second data read lines are arranged in one-to-one correspondence with the plurality of second signal receiving circuit groups, each of the second read control lines is connected with multiple second read control terminals of multiple the signal receiving circuits extending along the second direction in a corresponding one of the first signal receiving circuit groups, and each of the second read control lines is connected with multiple second data output terminals of multiple signal receiving circuits extending along the first direction in a corresponding one of the second signal receiving circuit groups, and the driving method further includes: after the plurality of second signal acquisition lines send the acquisition signals, applying turn-on signals to the multiple second read control terminals of the multiple signal receiving circuits extending along the second direction in the corresponding one of the first signal receiving circuit groups through the plurality of second read control lines respectively.

### BRIEF DESCRIPTION OF THE DRAWINGS

In order to clearly illustrate the technical solution of the embodiments of the present disclosure, the drawings of the embodiments will be briefly described in the following; it is obvious that the described drawings are only related to some embodiments of the present disclosure and thus are not limitative of the present disclosure.

FIG. 1 is a schematic diagram of a fingerprint identification module transmitting an ultrasonic wave;

FIG. 2 is a schematic diagram of a fingerprint identification module receiving an ultrasonic wave;

FIG. 3 is a schematic diagram of a fingerprint identification module performing fingerprint identification;

FIG. 4 is a schematic structural diagram of a fingerprint identification module;

FIG. 5 is a schematic diagram of a fingerprint identification circuit provided by an embodiment of the present disclosure;

FIG. 6 is a schematic diagram of a receiving focusing function provided by an embodiment of the present disclosure;

FIG. 7 is a timing chart of a driving method of the fingerprint identification circuit shown in FIG. 5;

FIG. 8 is a schematic diagram of another fingerprint identification circuit provided by an embodiment of the present disclosure;

FIG. 9 is a schematic diagram of a fingerprint identification module with transmitting focusing function provided by an embodiment of the disclosure;

FIG. 10 is a timing chart of a driving method of the fingerprint identification circuit shown in FIG. 8;

FIG. 11 is a timing chart of another driving method of the fingerprint identification circuit shown in FIG. 8;

FIG. 12 is a schematic diagram of another fingerprint identification circuit provided by an embodiment of the present disclosure;

FIG. 13 is a timing chart of a driving method of the fingerprint identification circuit shown in FIG. 12;

FIG. 14 is a timing chart of another driving method of the fingerprint identification circuit shown in FIG. 12;

FIG. 15 is a schematic diagram of another fingerprint identification circuit provided by an embodiment of the present disclosure;

FIG. 16 is a timing chart of a driving method of the fingerprint identification circuit shown in FIG. 15;

FIG. 17 is a timing chart of another driving method of the fingerprint identification circuit shown in FIG. 15;

FIG. 18 is a schematic diagram of another fingerprint identification circuit provided by an embodiment of the present disclosure;

FIG. 19 is a timing chart of a driving method of the fingerprint identification circuit shown in FIG. 18;

FIG. 20 is a timing chart of another driving method of the fingerprint identification circuit shown in FIG. 18;

FIG. 21 is a schematic diagram of another fingerprint identification circuit provided by an embodiment of the present disclosure;

FIG. 22A is a schematic diagram of another fingerprint identification circuit provided by an embodiment of the present disclosure;

FIG. 22B is a schematic diagram of another fingerprint identification circuit provided by an embodiment of the present disclosure

FIG. 23 is a timing chart of a driving method of the fingerprint identification circuit shown in FIG. 22A;

FIG. 24 is a timing chart of another driving method of the fingerprint identification circuit shown in FIG. 22B;

FIG. 25 is a schematic diagram of another fingerprint identification circuit provided by an embodiment of the present disclosure;

FIG. 26 is a timing chart of a driving method of the fingerprint identification circuit shown in FIG. 25;

FIG. 27 is a timing chart of another driving method of the fingerprint identification circuit shown in FIG. 25;

FIG. 28 is a schematic diagram of another fingerprint identification circuit provided by an embodiment of the present disclosure;

FIG. 29 is a timing chart of one driving method of the fingerprint identification circuit shown in FIG. 28;

FIG. 30 is a timing chart of another driving method of the fingerprint identification circuit shown in FIG. 28;

FIG. 31 is a schematic diagram of a fingerprint identification module provided by an embodiment of the present disclosure; and

FIG. 32 is a schematic diagram of a display device provided by an embodiment of the present disclosure.

### DETAILED DESCRIPTION

In order to make objects, technical details and advantages of the embodiments of the present disclosure apparent, the technical solutions of the embodiment will be described in a clearly and fully understandable way in connection with the drawings related to the embodiments of the present disclosure. It is obvious that the described embodiments are just a part but not all of the embodiments of the present disclosure. Based on the described embodiments herein, those skilled in the art can obtain other embodiment(s), without any inventive work, which should be within the scope of the present disclosure.

Unless otherwise defined, all the technical and scientific terms used herein have the same meanings as commonly understood by one of ordinary skill in the art to which the present disclosure belongs. The terms “first,” “second,” etc., which are used in the description and the claims of the present application for disclosure, are not intended to indicate any sequence, amount or importance, but distinguish various components. The terms “comprise,” “comprising,” “include,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly.

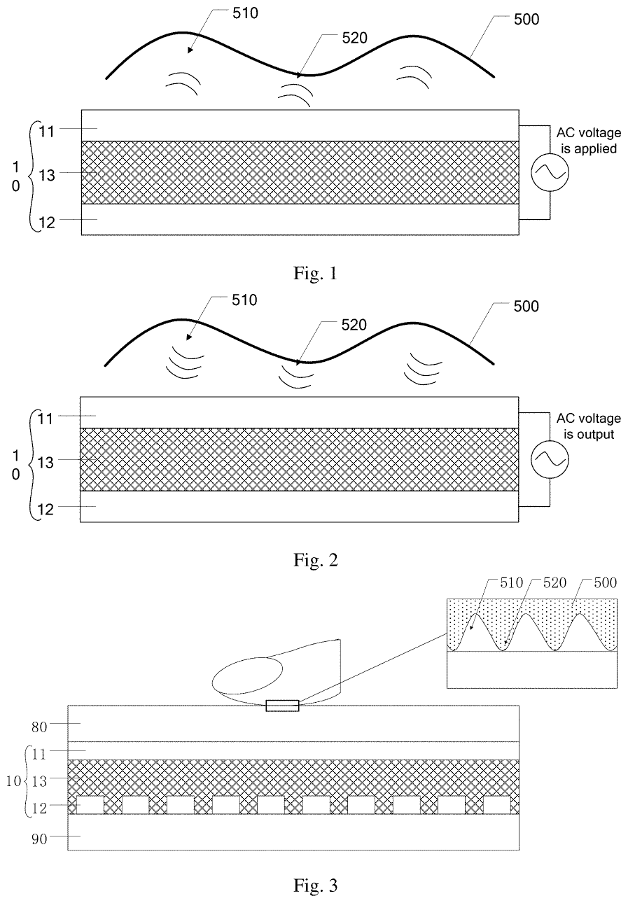

FIG. 1 is a schematic diagram of a fingerprint identification module transmitting an ultrasonic wave; FIG. 2 is a schematic diagram of a fingerprint identification module receiving an ultrasonic wave.

As illustrated by FIG. 1, the fingerprint identification module includes an ultrasonic sensor 10; the ultrasonic sensor 10 includes an upper electrode 11, a lower electrode 12, and a piezoelectric layer 13 located between the upper electrode 11 and the lower electrode 12; the piezoelectric layer 13 is made of a piezoelectric material and can be excited by voltage to generate an inverse piezoelectric effect. As illustrated by FIG. 1, upon an alternating voltage (AC voltage) being input to the upper electrode 11 and the lower electrode 12 (for example, the upper electrode 11 is grounded and an AC square wave is applied to the lower electrode 12), the piezoelectric layer 13 will deform due to the inverse piezoelectric effect or drive the film layers above and below the piezoelectric layer 13 to vibrate together, thereby generating an ultrasonic wave and transmitting it outward. It should be noted that, upon a cavity (e.g., an air cavity) being provided on a side of the upper electrode 11 away from the piezoelectric layer 13 or the side of the lower electrode 12 away from the piezoelectric layer 13, the ultrasonic wave transmitted by the ultrasonic sensor can be strengthened, so that the ultrasonic wave can be better transmitted.

As illustrated by FIG. 2, the ultrasonic wave transmitted by the ultrasonic sensor 10 are reflected by a fingerprint 500, and the reflected ultrasonic wave is converted into an alternating voltage in the piezoelectric layer; in this case, the upper electrode 11 is grounded, and the lower electrode 12 can be used as a receiving electrode to receive the alternating voltage generated by the piezoelectric layer. Because the fingerprint 500 includes valleys 510 and ridges 520, their reflecting abilities to ultrasonic wave are different (the valleys 510 have stronger reflecting abilities to ultrasonic wave), resulting in different intensities of ultrasonic wave reflected back by the valleys 510 and the ridges 520. Therefore, it can be judged whether the ultrasonic wave are reflected by valleys or ridges by the alternating voltages received by the receiving electrode.

FIG. 3 is a schematic diagram of a fingerprint identification module performing fingerprint identification. As illustrated by FIG. 3, the fingerprint identification module includes an upper electrode 11, a plurality of lower electrodes 12, a piezoelectric layer 13 located between the upper electrode 11 and the plurality of lower electrodes 12, a substrate 80 located on a side of the upper electrode 11 away from the piezoelectric layer 13, and a protective layer 90 located on a side of the plurality of lower electrodes 12 away from the piezoelectric layer 13. The ultrasonic sensor 10 formed by the lower electrode 12, the piezoelectric layer 13, and the plurality of upper electrodes 11 can transmit an ultrasonic wave as well as receive an ultrasonic wave, that is, the ultrasonic sensor 10 serves as both an ultrasonic emission sensor and an ultrasonic reception sensor. Upon a fingerprint contacting the substrate 80, the ultrasonic wave transmitted by the ultrasonic sensor 10 is reflected by the fingerprint 500, and the reflected ultrasonic wave is converted into an alternating voltage in the piezoelectric layer; in this case, the upper electrode 11 is grounded, and a plurality of lower electrodes 12 can be used as receiving electrodes, so that alternating voltages generated by the piezoelectric layer can be received at different positions. Because the fingerprint 500 includes valleys 510 and ridges 520, their reflecting abilities to ultrasonic wave are different (the valleys 510 have stronger reflecting abilities to ultrasonic wave), resulting in different intensities of ultrasonic wave reflected back by the valleys 510 and the ridges 520. Therefore, the position information of the valleys and the ridges in the fingerprint 500 can be obtained by alternating voltages received by the plurality of lower electrodes 12, so that fingerprint identification can be achieved.

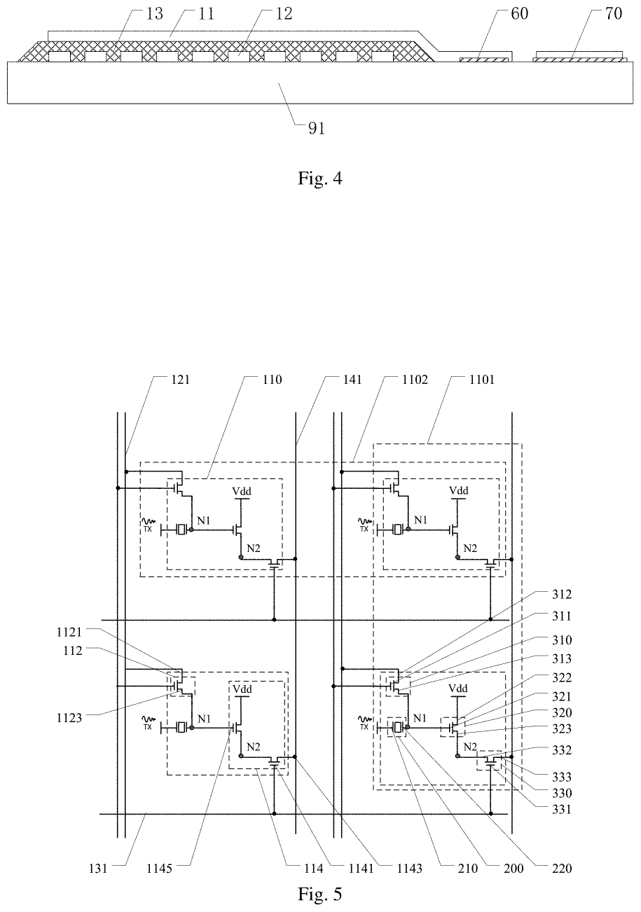

FIG. 4 is a schematic structural diagram of a fingerprint identification module. As illustrated by FIG. 4, the upper electrode 11, the lower electrode 12, and the piezoelectric layer 13 can all be formed on the same side of the thin film transistor substrate 91. The fingerprint identification module further includes a bias resistor 60 and a bonding pad 70; the bias resistor 60 can be used to calibrate the voltage, and bonding pad 70 can be used to bond external circuits.

In the research, the inventor(s) of the application noticed that the reasons of that the ultrasonic fingerprint detection performance was poor are the weak ultrasonic fingerprint signal and the large interference caused by the need to use high frequency drive in ultrasonic detection.

With this regard, the embodiments of the present disclosure provide a fingerprint identification circuit, a driving method of the fingerprint identification circuit, a fingerprint identification module, and a display device. The fingerprint identification circuit includes a plurality of signal receiving circuits arranged in an array along a first direction and a second direction to form a plurality of first signal receiving circuit groups arranged along the first direction and a plurality of second signal receiving circuit groups arranged along the second direction; and a plurality of first signal acquisition lines, each of the first signal acquisition lines extends along a second direction, the plurality of first signal acquisition lines are arranged along the first direction, each of the signal receiving circuits includes an acquisition sub-circuit and an output sub-circuit, the acquisition sub-circuit includes a first acquisition signal input terminal and a first acquisition signal output terminal, the output sub-circuit includes a first read control terminal, a first data output terminal, and a data input terminal, the first acquisition signal output terminal and the data input terminal are connected to a first node, the first node is configured to be connected with a receiving electrode of the ultrasonic sensor, the plurality of first signal acquisition lines are arranged in one-to-one correspondence with the plurality of first signal receiving circuit groups, and each of the first signal acquisition lines is connected with multiple first acquisition signal input terminals of multiple signal receiving circuits arranged along the second direction in a corresponding one of the plurality of first signal receiving circuit groups. Therefore, the fingerprint identification circuit can apply acquisition signals with different time sequences to the plurality of first signal receiving circuits through the plurality of first signal acquisition lines, thereby achieving a receiving focusing function and improving fingerprint identification performance Specifically, the fingerprint identification circuit can improve signal quantity and signal-to-noise ratio, and can also achieve read and operation at the same time, thus improving the speed and efficiency of fingerprint identification while ensuring high signal-to-noise ratio.

Hereinafter, the fingerprint identification circuit, the driving method of the fingerprint identification circuit, the fingerprint identification module, and the display device provided by the embodiments of the present disclosure will be described in detail with reference to the accompanying drawings.

An embodiment of the present disclosure provides a fingerprint identification circuit. FIG. 5 is a schematic diagram of a fingerprint identification circuit provided by an embodiment of the present disclosure. As illustrated by FIG. 5, the fingerprint identification circuit includes a plurality of signal receiving circuits 110 and a plurality of first signal acquisition lines 121. The plurality of signal receiving circuits 110 are arranged in an array along a first direction and a second direction to form a plurality of first signal receiving circuit groups 1101 arranged along the first direction and a plurality of second signal receiving circuit groups 1102 arranged along the second direction. For example, as illustrated by FIG. 5, the first signal receiving circuit group 1101 can be a column of signal receiving circuits 110 arranged in the second direction, and the second signal receiving circuit group 1102 can be a row of signal receiving circuits 110 arranged in the first direction. The first signal acquisition line 121 extends in a second direction, and a plurality of first signal acquisition lines 121 are arranged in the first direction. The extending direction of the first signal acquisition line 121 is the same as the arranging direction of the signal receiving circuits 110 in the first signal receiving circuit group 1101.

It should be noted that, the first signal receiving circuit group and the second signal receiving circuit group are only divided according to signal circuits arranged in different directions, and it does not refer to that the first signal circuit group and the second signal circuit group include different signal circuits. For example, for a certain signal circuit, it may belong to both a certain first signal circuit group and a certain second signal circuit group. For another example, the first signal circuit group can be a signal circuit column in the signal circuit array, and the second signal circuit group can be a signal circuit row in the signal circuit array.

As illustrated by FIG. 5, the signal receiving circuit 110 includes an acquisition sub-circuit 112 and an output sub-circuit 114. The acquisition sub-circuit 112 includes a first acquisition signal input 1121 and a first acquisition signal output 1123. The output sub-circuit 114 includes a first read control terminal 1141, a first data output terminal 1143, and a data input terminal 1145. The first acquisition signal output terminal 1123 and the data input terminal 1145 are connected to a first node N1 configured to be connected with a receiving electrode 220 of the ultrasonic sensor 200. In this case, the first acquisition signal output terminal 1123 and the data input terminal 1145 are both connected with the receiving electrode 220 of the ultrasonic sensor 200. The plurality of first signal acquisition lines 121 are arranged in one-to-one correspondence with the plurality of first signal receiving circuit groups 1101, and each of the first signal acquisition lines 121 is connected with multiple first acquisition signal input terminals 1121 of multiple signal receiving circuits 110 arranged along a second direction in a corresponding one of the first signal receiving circuit groups 1101.

In the fingerprint identification circuit provided by the present embodiment, the plurality of first signal acquisition lines and the plurality of first signal receiving circuit groups are arranged in one-to-one correspondence, and each of the first signal acquisition lines is connected with the multiple first acquisition signal input terminals of the multiple signal receiving circuits arranged along the second direction in the corresponding one of the first signal receiving circuit groups; that is, the plurality of first signal receiving circuit groups are connected with different first signal acquisition lines respectively. Upon the ultrasonic wave transmitted by the ultrasonic sensor being reflected by a finger, the reflected echo reaches the first signal receiving circuit groups arranged along the first direction at different times, so acquisition signals with different time sequences can be applied to the plurality of first signal receiving circuits through the plurality of first signal acquisition lines to acquire the reflected signals generated by the reflected echo received by the ultrasonic sensors corresponding to different first signal receiving circuit groups, and the receiving focusing function of the plurality of first signal receiving circuit groups arranged along the first direction can be achieved by performing weighted summation on the reflected signals, so that fingerprint data with higher intensity and higher signal-to-noise ratio can be obtained. Therefore, the fingerprint identification circuit can apply acquisition signals with different time sequences to the plurality of first signal receiving circuits through the plurality of first signal acquisition lines, thereby achieving a receiving focusing function and improving fingerprint identification performance It should be noted that the first direction can be the row direction and the second direction can be the column direction. In this case, the fingerprint identification circuit can achieve a column receiving focusing function.

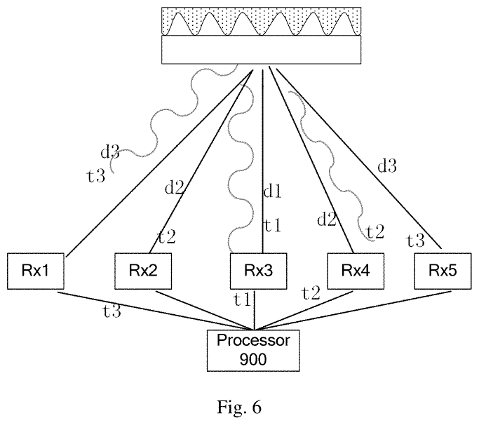

FIG. 6 is a schematic diagram of a receiving focusing function according to an embodiment of the present disclosure; Rx1 to Rx5 in FIG. 6 respectively represent lateral views of receiving electrodes corresponding to a plurality of first signal receiving circuit groups arranged in the first direction. As illustrated by FIG. 6, upon the ultrasonic wave transmitted by the ultrasonic sensor being reflected by the finger, the reflected echo will be transmitted to the ultrasonic sensor at different positions, so the receiving electrodes at different positions (e.g., Rx1, Rx2, Rx3, Rx4 and Rx5) will also receive the reflected signal at different times. In this case, according to an arrival time of reflected echo, acquisition signals with different time sequences can be applied to the plurality of first signal receiving circuits through the plurality of first signal acquisition lines to acquire reflected signals generated by reflected echo received by reflection electrodes corresponding to different first signal receiving circuit groups; after all the reflected signals are collected, the reflected signals are summed with different weights by the processor 900, and finally enhanced fingerprint data (fingerprint valley ridge signal) is obtained. For example, a distance between the finger and Rx3 is d1, a time for the reflected echo to reach Rx3 is t1, a distance between the finger and Rx2 and Rx4 is d2, a time for the reflected echo to reach Rx2 and Rx4 is t2, a time for the reflected echo to reach Rx2 and Rx4 is t2, a distance between the finger and Rx1 and Rx5 is d3, a time for the reflected echo to reach Rx1 and Rx5 is t3, t1 is less than t2, t2 is less than t3. Therefore, an acquisition signal can be applied to the first signal receiving circuit corresponding to Rx3 at the first moment through the first signal acquisition line corresponding to Rx3, acquisition signals can be applied to the first signal receiving circuits corresponding to Rx2 and Rx4 at the second moment delayed from the first moment through the first signal acquisition lines corresponding to Rx2 and Rx4, and acquisition signals can be applied to the first signal receiving circuits corresponding to Rx1 and Rx5 at the third moment delayed from the second moment through the first signal acquisition lines corresponding to Rx1 and Rx5, to acquire the reflected signals of Rx1, Rx2, Rx3, Rx4 and Rx5. It should be noted that the first moment, the second moment, and the third moment need to be accurately set, for example, the time interval between the second moment and the first moment can be (d3-d1)/sound speed of ultrasonic wave.

In some examples, as illustrated by FIG. 5, the fingerprint identification circuit further includes a plurality of first read control lines 131 and a plurality of first data read lines 141; each of the first read control lines 131 extends in the first direction, and the plurality of first read control lines 131 are arranged in the second direction; each of the first data read lines 141 extends in a second direction, and the plurality of first data read lines 141 are arranged in the first direction. The plurality of first read control lines 131 are arranged in one-to-one correspondence with the plurality of second signal receiving circuit groups 1102; the plurality of first data read lines 141 are arranged in one-to-one correspondence with the plurality of first signal receiving circuit groups 1101, each of the first read control lines 131 is connected with multiple first read control terminals 1141 of multiple signal receiving circuits 110 extending in the first direction in a corresponding one of the second signal receiving circuit groups 1102, and each of the first read control lines 141 is connected with multiple first data output terminals 1143 of multiple signal receiving circuits 110 extending in the second direction in a corresponding one of the first signal receiving circuit groups 1101. Thus, the reflected signals as collected can be output through the above-mentioned plurality of first read control lines 131 and the plurality of first data read lines 141.

In some examples, as illustrated by FIG. 5, the acquisition sub-circuit 112 includes a first thin film transistor 310; the first thin film transistor 310 includes a first gate electrode 311, a first source electrode 312, and a first drain electrode 313. In this case, the fingerprint identification circuit further includes a plurality of first acquisition control lines 151, each of which extends in a second direction; the plurality of first acquisition control lines 151 are arranged in the first direction; and the plurality of first acquisition control lines 151 are arranged one-to-one in correspondence with the plurality of first signal receiving circuit groups 1101. Each of the first acquisition control lines 151 is connected with the first gate electrodes 311 of multiple signal receiving circuits 110 arranged along the second direction in a corresponding one of the first signal receiving circuit groups 1101. The first source electrode 312 is the first acquisition signal input terminal 1121 and the first drain electrode 313 is the first acquisition signal output terminal 1123. That is, each of the first signal acquisition lines 121 is connected with the multiple first source electrodes 312 of the multiple signal receiving circuits 110 arranged in the second direction in a corresponding one of the first signal receiving circuit groups 1101; the first drain electrode 313 is connected to the first node N1.

In some examples, as illustrated by FIG. 5, the output sub-circuit 114 includes a second thin film transistor 320 and a third thin film transistor 330. The second thin film transistor 320 includes a second gate electrode 321, a second source electrode 322, and a second drain electrode 323; the third thin film transistor 330 includes a third gate electrode 331, a third source electrode 332, and a third drain electrode 333. The second gate electrode 321 is connected to the first node N1; the second source electrode 322 is configured to be connected with a high voltage source Vdd; and the second drain electrode 323 is connected to the second node N2. The third source electrode 332 is connected to the second node N2; the second gate electrode 321 is the data input terminal 1145; the third gate electrode 331 is the first read control terminal 1141; and the third drain electrode 333 is the first data output terminal 1143.

For example, the second thin film transistor 320 can be an oxide thin film transistor, such as an indium gallium zinc oxide (IGZO) thin film transistor. Because the voltage of the first node N1 may leak from the second thin film transistor, and the leakage flow level of the oxide thin film transistor, such as IGZO thin film transistor, is 10⁻¹⁵A. In the case where the second thin film transistor 320 is an oxide thin film transistor, the overall leakage current of the drive circuit can be reduced, thus ensuring the stability of the reflected signal on the first node N1, and thus improving the fingerprint identification performance of the fingerprint identification module.

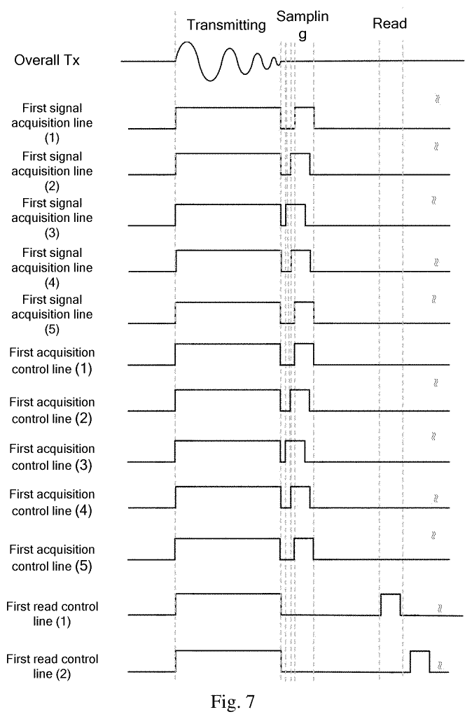

FIG. 7 is a timing chart of a driving method of the fingerprint identification circuit shown in FIG. 5; FIG. 7 is a timing chart of a driving method for driving a plurality of first signal receiving circuit groups (Rx1-Rx5) arranged in the first direction shown in FIG. 6 to achieve a receiving focusing function. As illustrated by FIG. 7, in the ultrasonic transmitting stage, both the first signal acquisition line and the first acquisition control line are applied with a reference voltage. In this case, the reference voltage on the first node can be used not only to transmit an ultrasonic wave with the driving voltage on the driving electrode of the ultrasonic sensor, but also for resetting. In the reflected signal acquisition stage, in order to acquire reflected signals of Rx1, Rx2, Rx3, Rx4 and Rx5, the first signal acquisition line and the first acquisition control line corresponding to Rx3 are applied with acquisition voltages at the first moment; the first signal acquisition lines and the first acquisition control lines corresponding to Rx2 and Rx4 are applied with acquisition signals at the second moment delayed from the first time; and the first signal acquisition lines and the first acquisition control lines corresponding to Rx1 and Rx5 are applied with acquisition signals at the third moment delayed from the second moment. After the reflected signals are collected, turn-on signals are sequentially applied to the plurality of first read control lines to read the reflected signals through the plurality of first data read lines. Finally, weighted summation of these reflected signals can be performed to achieve the receiving focusing function on the plurality of first signal receiving circuit groups arranged along the first direction. For example, the reference voltage, the acquisition signal, and the turn-on signal are all high levels, and the voltage of the acquisition signal is greater than the reference voltage. For example, the reference voltage can be 0-3.3V, and the voltage of the acquisition signal can be about 10V. It should be noted that, FIG. 7 is only one example of a timing chart illustrating a driving method of the fingerprint identification circuit to achieve the receiving focusing function provided by the embodiment of the present disclosure. The receiving focusing function provided by the embodiment of the present disclosure is not limited to five first signal receiving circuit groups, and other number of first signal receiving circuit groups can also achieve the receiving focusing function. In addition, the high-level acquisition signal can lift an alternating voltage received by the receiving electrode to obtain a detection signal with a larger contrast ratio.

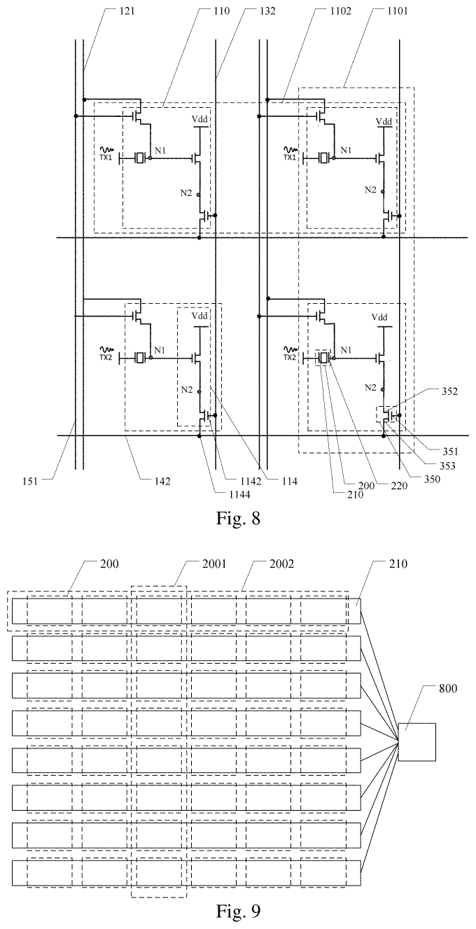

FIG. 8 is a schematic diagram of another fingerprint identification circuit according to an embodiment of the present disclosure. As illustrated by FIG. 8, the fingerprint identification circuit is not provided with the above-mentioned first read control line and first data read line. The fingerprint identification circuit includes a plurality of second read control lines 132 and a plurality of second data read lines 142; each of the second read control lines 132 extends in a second direction, and the plurality of second read control lines 132 are arranged in the first direction. Each of the second data read lines 142 extends in a first direction, and the plurality of second data read lines 142 are arranged in the second direction. The output sub-circuit 114 includes a second read control terminal 1142 and a second data output terminal 1144; the plurality of second read control lines 132 and the plurality of first signal receiving circuit groups 1101 are arranged in one-to-one correspondence; and the plurality of second data read lines 142 and the plurality of second signal receiving circuit groups 1102 are arranged in one-to-one correspondence; each of the second read control lines 132 is connected with multiple second read control terminals 1142 of the multiple signal receiving circuits 110 extending in a second direction in a corresponding one of the first signal receiving circuit groups 1102; and each of the second read control lines 142 is connected with multiple second data output terminals 1144 of the multiple signal receiving circuits 110 extending in a first direction in a corresponding one of the second signal receiving circuit groups 1101. Thus, the reflected signals as collected can be output through the plurality of second read control lines 132 and the plurality of second data read lines 142 described above.

The fingerprint identification circuit shown in FIG. 8 can be applied to a fingerprint identification module with a transmitting focusing function. In this case, the fingerprint identification circuit shown in FIG. 8 can not only achieve the receiving focusing function on the plurality of first signal receiving circuit groups arranged along the first direction, but also can apply turn-on signals to the plurality of signal receiving circuits arranged along the first direction in the corresponding one of the second signal receiving circuit groups through the second read control lines when transmitting focusing is performed on a plurality of ultrasonic sensor groups arranged along the second direction in the fingerprint identification module, and reflected signals are read through the plurality of second data read lines to improve the signal read efficiency.

In some examples, as illustrated by FIG. 8, the output sub-circuit 114 includes a second thin film transistor 320 and a fifth thin film transistor 350. The second thin film transistor 320 includes a second gate electrode 321, a second source electrode 322, and a second drain electrode 323; the fifth thin film transistor 350 includes a fifth gate electrode 351, a fifth source electrode 352, and a fifth drain electrode 353. The second gate electrode 321 is connected to the first node N1, the second source electrode 322 is configured to be connected with the high voltage source Vdd, the second drain electrode 323 is connected to the second node N2, the fifth source electrode 352 is connected to the second node N2. The second gate electrode 321 is the data input terminal 1145; the fifth gate electrode 351 is the second read control terminal 1142; and the fifth drain electrode 353 is the second data output terminal 1144.

FIG. 9 is a schematic diagram of a fingerprint identification module with transmitting focusing function according to an embodiment of the present disclosure. As illustrated by FIG. 9, a plurality of ultrasonic sensors 200 are arranged in an array along a first direction and a second direction to form a plurality of first ultrasonic sensor groups 2001 arranged in the first direction and a plurality of second ultrasonic sensor groups 2002 arranged in the second direction. Transmitting electrodes 210 of the plurality of ultrasonic sensors 200 arranged in the second direction in each of the first ultrasonic sensor groups 2001 are different, and the plurality of ultrasonic sensors 200 arranged in the first direction in each of the second ultrasonic sensor groups 2002 share one strip-shaped transmitting electrode 210. Therefore, the fingerprint identification module can achieve the transmitting focusing function by applying driving voltages with different timings to different strip-shaped transmitting electrodes 210. In this case, the ultrasonic wave at the position corresponding to the specific second ultrasonic sensor group in the fingerprint identification module is enhanced. If the above-mentioned first read control line extending in the first direction and the first data read line extending in the second direction are used to read the reflected signal, in addition to the reflected signal of the second ultrasonic sensor group corresponding to the position where the ultrasonic wave is enhanced, the reflected signals of other ultrasonic sensors can also be read, so the signal reading efficiency is low. Upon the fingerprint identification module shown in FIG. 9 adopting the fingerprint identification module shown in FIG. 8, only the reflected signal of the second ultrasonic sensor group corresponding to the enhanced position can be read by the second read control line extending in the second direction and the second data read line extending in the first direction, thus improving the signal read efficiency. For example, as illustrated by FIG. 9, different strip-shaped transmitting electrodes 210 are connected with a transmitting driver 800 through different driving lines.

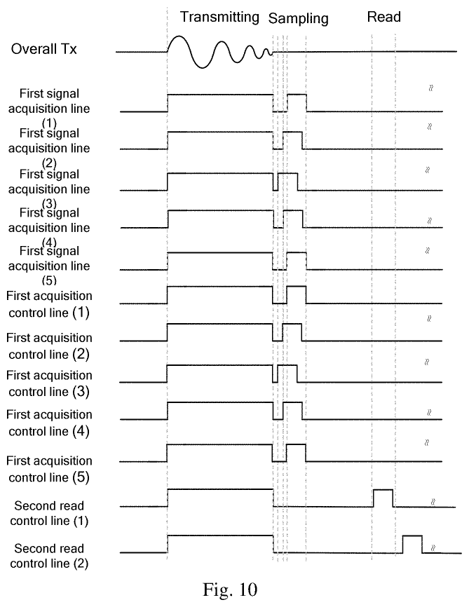

FIG. 10 is a timing chart of a driving method of the fingerprint identification circuit shown in FIG. 8; FIG. 10 is a timing chart of a driving method for driving a plurality of first signal receiving circuit groups (Rx1-Rx5) arranged in the first direction shown in FIG. 6 to achieve a receiving focusing function. As illustrated by FIG. 10, in the ultrasonic transmitting stage, all driving electrodes are applied with driving voltages simultaneously, and the first signal acquisition lines and the first acquisition control lines are applied with reference voltages. In this case, the reference voltage on the first node can be used not only to transmit an ultrasonic wave with the driving voltage on the driving electrode of the ultrasonic sensor, but also for resetting. In the reflected signal acquisition stage, in order to acquire reflected signals of Rx1, Rx2, Rx3, Rx4 and Rx5, the first signal acquisition line and the first acquisition control line corresponding to Rx3 are applied with acquisition voltage at the first moment; the first signal acquisition line and the first acquisition control line corresponding to Rx2 and Rx4 are applied with acquisition signals at the second moment delayed from the first moment; and the first signal acquisition lines and the first acquisition control lines corresponding to Rx1 and Rx5 are applied with acquisition signals at the third moment delayed from the second moment. After the collection of the reflected signal is completed, turn-on signals are sequentially applied to the plurality of second read control lines, so that the reflected signals are read out through the plurality of second data read lines. Finally, weighted summation of these reflected signals can be performed to achieve the receiving focusing function on the plurality of first signal receiving circuit groups arranged along the first direction. For example, the reference voltage, the acquisition signal, and the turn-on signal are all high levels, and the voltage of the acquisition signal is greater than the reference voltage. It should be noted that FIG. 10 is only one example of a timing chart illustrating a driving method for a fingerprint identification circuit to achieve a receiving focusing function provided by the embodiment of the present disclosure. The receiving focusing function provided by the embodiment of the present disclosure is not limited to five first signal receiving circuit groups, and other number of first signal receiving circuit groups can also achieve the receiving focusing function.

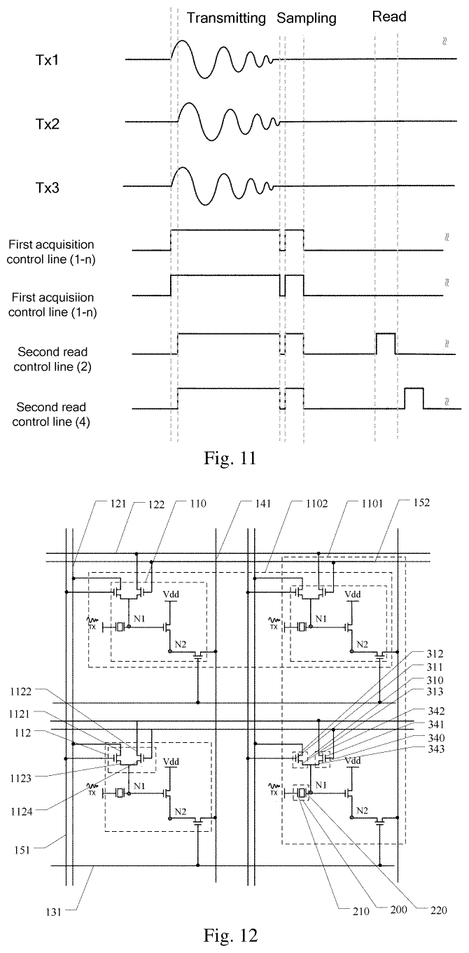

FIG. 11 is a timing chart of another driving method of the fingerprint identification circuit shown in FIG. 8; FIG. 11 is a timing chart of a driving method for driving the plurality of second ultrasonic sensor groups arranged in the second direction shown in FIG. 9 to achieve the transmitting focusing function. As illustrated by FIG. 11, in the ultrasonic transmission stage, driving voltages are applied to Tx1 and Tx3 at the fourth moment and then to Tx2 at the fifth moment, so that ultrasonic focusing can be achieved at the position corresponding to Tx2 (directly above Tx2). All the first signal acquisition lines and the first acquisition control lines are applied with reference voltages. In this case, the reference voltage on the first node can be used not only for transmitting an ultrasonic wave with the driving voltage on the driving electrode of the ultrasonic sensor, but also for resetting. In the reflected signal acquisition stage, all the first signal acquisition lines and the first acquisition control lines are applied with acquisition signals to acquire reflected signals. After the collection of the reflected signal is completed, the turn-on signal is only applied to the second read control line corresponding to the ultrasonic focusing position, so that only the reflected signal of the second ultrasonic sensor group corresponding to the enhanced position is read out by the ultrasonic wave, thereby improving the signal read efficiency.

It should be noted that, upon the fingerprint identification circuit shown in FIG. 8 being applied to the fingerprint identification module with transmitting focusing function, a two-dimensional focusing function can be achieved by first performing receiving focusing of the plurality of first signal receiving circuit groups arranged along the first direction and then performing transmitting focusing of the plurality of second ultrasonic sensor groups arranged along the second direction. Then, the fingerprint information obtained by the two operations is further processed to obtain more accurate fingerprint information, thus further improving the fingerprint identification performance.

FIG. 12 is a schematic diagram of another fingerprint identification circuit according to an embodiment of the present disclosure. As illustrated by FIG. 12, in addition to the above-mentioned first signal acquisition lines 121, the fingerprint identification circuit further includes a plurality of second signal acquisition lines 122, each of the second signal acquisition lines 122 extends in a first direction; and the plurality of second signal acquisition lines 122 are arranged in the second direction. The acquisition sub-circuit 112 further includes a second acquisition signal input terminal 1122 and a second acquisition signal output terminal 1124. The second acquisition signal output terminal 1124 is connected to the first node N1. The plurality of second signal acquisition lines 122 are arranged in one-to-one correspondence with the plurality of second signal receiving circuit groups 1102; and each of the second signal acquisition lines 122 is connected with multiple second acquisition signal input terminals 1122 of the multiple signal receiving circuits 441 arranged along the first direction in the corresponding one of the second signal receiving circuit groups 1102. Because the plurality of second signal acquisition lines is arranged in one-to-one correspondence with the plurality of second signal receiving circuit groups, each of the second signal acquisition lines is connected with multiple second acquisition signal input terminals of the multiple signal receiving circuits arranged along a first direction in a corresponding one of the second signal receiving circuit groups; that is, the plurality of second signal receiving circuit groups are connected with different second signal acquisition lines respectively. Upon the ultrasonic wave transmitted by the ultrasonic sensor being reflected by the finger, the time of the reflected echo reaching the second signal receiving circuit group arranged along the second direction is different, so acquisition signals with different time sequences can be applied to the plurality of second signal receiving circuits through the plurality of second signal acquisition lines to acquire the reflected signals generated by the reflected echo received by the ultrasonic sensors corresponding to different second signal receiving circuit groups. The receiving focusing function can be achieved by performing weighted summation of the reflected signals, so that fingerprint data with higher intensity and higher signal-to-noise ratio can be obtained. Therefore, the fingerprint identification circuit can apply acquisition signals with different time sequences to a plurality of second signal receiving circuits through a plurality of second signal acquisition lines, thereby achieving the receiving focusing function and improving the fingerprint identification performance It should be noted that the first direction can be the row direction and the second direction can be the column direction. In this case, the fingerprint identification circuit can achieve the row receiving focusing function through the second signal acquisition line.

It should be noted that the fingerprint identification circuit shown in FIG. 12 can respectively achieve the receiving focusing function on a plurality of first receiving circuit groups arranged along the first direction and a plurality of second receiving circuit groups arranged along the second direction, and then, the fingerprint information obtained by the two operations is further processed to obtain more accurate fingerprint information, thus, the fingerprint identification circuit can achieve the two-dimensional receiving focusing function, thus further improving the fingerprint identification performance.

In some examples, as illustrated by FIG. 12, the acquisition sub-circuit 112 further includes a fourth thin film transistor 340; the fourth thin film transistor 340 includes a fourth gate electrode 341, a fourth source electrode 342, and a fourth drain electrode 343. In this case, the fingerprint identification circuit further includes a plurality of second acquisition control lines 152. Each of the second acquisition control lines 152 extends in a first direction; and the plurality of second acquisition control lines 152 are arranged in the second direction. The plurality of second acquisition control lines 152 are arranged in one-to-one correspondence with the plurality of second signal receiving circuit groups 1102. Each of the second acquisition control lines 152 is connected with the fourth gate electrode 341 of the plurality of signal receiving circuits 110 arranged along the first direction in the corresponding one of the second signal receiving circuit groups 1102. The fourth source electrode 342 is the second acquisition signal input terminal 1122; and the fourth drain electrode 343 is the second acquisition signal output terminal 1124. That is, each of the second signal acquisition lines 122 is connected with the fourth source electrode 342 of the plurality of signal receiving circuits 110 arranged in the first direction in the corresponding one of the second signal receiving circuit groups 1102. The fourth drain electrode 343 is connected to the first node N1.

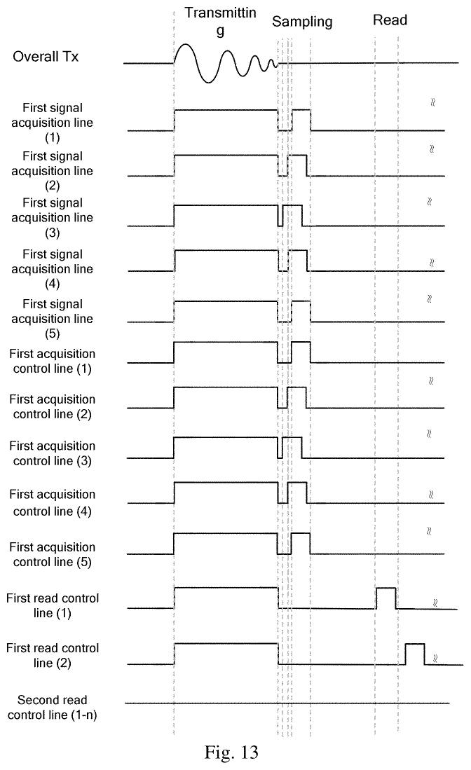

FIG. 13 is a timing chart of a driving method of the fingerprint identification circuit shown in FIG. 12; FIG. 13 is a timing chart of a driving method for driving a plurality of first signal receiving circuit groups (Rx1-Rx5) arranged in the first direction shown in FIG. 6 to achieve a receiving focusing function. As illustrated by FIG. 13, in the ultrasonic transmitting stage, both the first signal acquisition line and the first acquisition control line are applied with a reference voltage. In this case, the reference voltage on the first node can be used not only to transmit an ultrasonic wave with the driving voltage on the driving electrode of the ultrasonic sensor, but also for resetting. In the reflected signal acquisition stage, in order to acquire reflected signals of Rx1, Rx2, Rx3, Rx4 and Rx5, the first signal acquisition line and the first acquisition control line corresponding to Rx3 are applied with an acquisition voltage at the first moment; the first signal acquisition lines and the first acquisition control lines corresponding to Rx2 and Rx4 are applied with acquisition signals at the second moment delayed from the first moment; and the first signal acquisition lines and the first acquisition control lines corresponding to Rx1 and Rx5 are applied with acquisition signals at the third moment delayed from the second moment. After the reflected signals are collected, turn-on signals are sequentially applied to the plurality of first read control lines to read the reflected signal through the plurality of first data read lines. Finally, the weighted summation of these reflected signals can be performed to achieve the receiving focusing function on the plurality of first signal receiving circuit groups arranged along the first direction. For example, the reference voltage, the acquisition signal, and the turn-on signal are all high levels, and the voltage of the acquisition signal is greater than the reference voltage. It should be noted that FIG. 13 is only one example of a timing chart illustrating a driving method of a fingerprint identification circuit to achieve a receiving focusing function provided by the embodiment of the present disclosure. The receiving focusing function provided by the embodiment of the present disclosure is not limited to five first signal receiving circuit groups, and other number of first signal receiving circuit groups can also achieve the receiving focusing function.

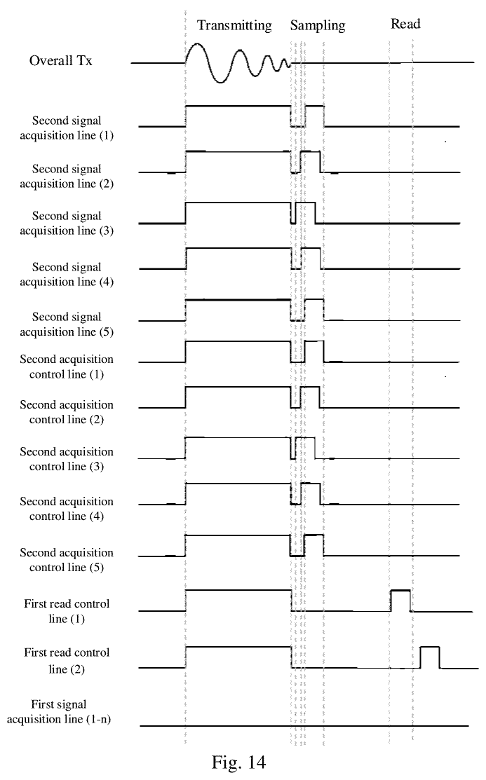

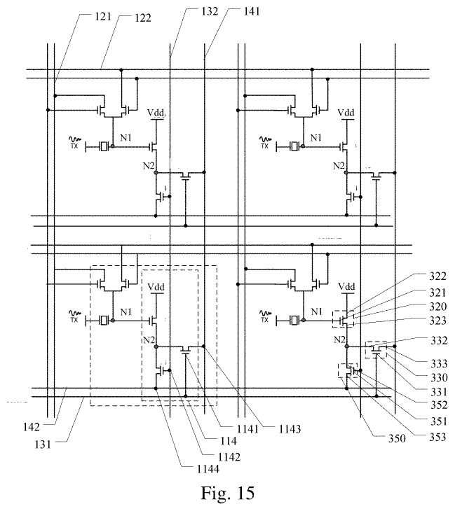

FIG. 14 is a timing chart of another driving method of the fingerprint identification circuit shown in FIG. 12; FIG. 14 is a timing chart of a driving method for driving a plurality of second signal receiving circuit groups arranged in the second direction to achieve a receiving focusing function. Similar to the driving method shown in FIG. 13, in the ultrasonic transmitting stage, the second signal acquisition line and the second acquisition control line are both applied with a reference voltage. In this case, the reference voltage on the first node can be used not only to transmit an ultrasonic wave with the driving voltage on the driving electrode of the ultrasonic sensor, but also for resetting. In the reflected signal acquisition stage, acquisition signals with different timing sequences can be applied to the plurality of second signal receiving circuit groups arranged along the second direction to acquire reflected signals of the plurality of second signal receiving circuit groups arranged along the second direction. After the reflected signals are collected, turn-on signals are sequentially applied to the plurality of first read control lines to read the reflected signal through the plurality of first data read lines. Finally, the weighted summation of these reflected signals can be performed to achieve the receiving focusing function on the plurality of first signal receiving circuit groups arranged along the first direction. For example, the reference voltage, the acquisition signal, and the turn-on signal are all high levels, and the voltage of the acquisition signal is greater than the reference voltage.

FIG. 15 is a schematic diagram of another fingerprint identification circuit according to an embodiment of the present disclosure. As illustrated by FIG. 15, the output sub-circuit 114 includes a second thin film transistor 320, a third thin film transistor 330, and a fifth thin film transistor 350. The second thin film transistor 320 includes a second gate electrode 321, a second source electrode 322, and a second drain electrode 323; the third thin film transistor 330 includes a third gate electrode 331, a third source electrode 332, and a third drain electrode 333; the fifth thin film transistor 350 includes a fifth gate electrode 351, a fifth source electrode 352, and a fifth drain electrode 353. The second gate electrode 321 is connected to the first node N1; the second source electrode 322 is configured to be connected with the high voltage source Vdd; the second drain electrode 323 is connected to the second node N2; the third source electrode 332 is connected to the second node N2; the second gate electrode 331 is the data input terminal 1145; the third gate electrode 331 is the first read control terminal 1141; the third drain electrode 333 is the first data output terminal 1143; the fifth source electrode 352 is connected to the second node N2; the fifth gate electrode 351 is the second read control terminal 1142; and the fifth drain electrode 353 is the second data output terminal 1144.

In addition, as illustrated by FIG. 15, the fingerprint identification circuit is simultaneously provided with the above-mentioned plurality of first read control lines 131, the plurality of first data read lines 141, the plurality of second read control lines 132, and the plurality of second data read lines 142. The specific arrangement of the plurality of first read control lines 131, the plurality of first data read lines 141, the plurality of second read control lines 132, and the plurality of second data read lines 142 can be seen in the related description of the previous embodiments, and will not be repeated here.

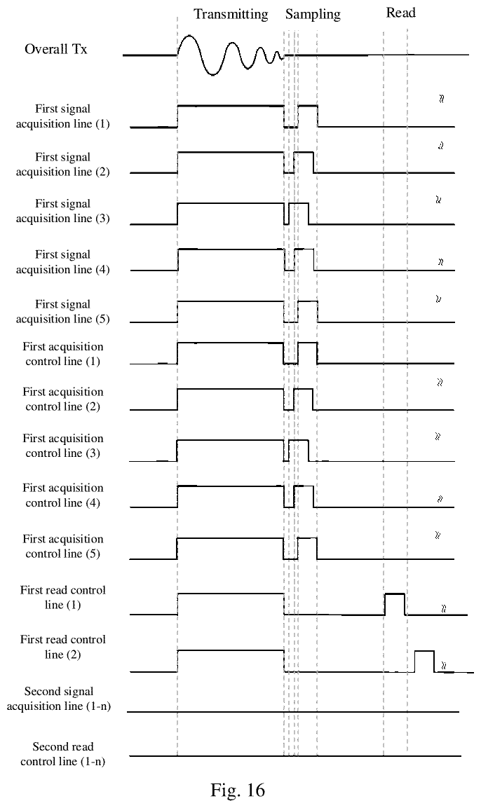

FIG. 16 is a timing chart of a driving method of the fingerprint identification circuit shown in FIG. 15; FIG. 16 is a timing chart of a driving method for driving a plurality of first signal receiving circuit groups (Rx1-Rx5) arranged in the first direction shown in FIG. 6 to achieve a receiving focusing function. As illustrated by FIG. 16, in the ultrasonic transmitting stage, both the first signal acquisition line and the first acquisition control line are applied with a reference voltage. In this case, the reference voltage on the first node can be used not only to transmit an ultrasonic wave with the driving voltage on the driving electrode of the ultrasonic sensor, but also for resetting. In the reflected signal acquisition stage, in order to acquire reflected signals of Rx1, Rx2, Rx3, Rx4 and Rx5, the first signal acquisition line and the first acquisition control line corresponding to Rx3 are applied with an acquisition voltage at the first moment; the first signal acquisition lines and the first acquisition control lines corresponding to Rx2 and Rx4 are applied with acquisition signals at the second moment delayed from the first moment; and the first signal acquisition lines and the first acquisition control lines corresponding to Rx1 and Rx5 are applied with acquisition signals at the third moment delayed from the second moment. After the reflected signals are collected, turn-on signals are sequentially applied to the plurality of first read control lines to read the reflected signal through the plurality of first data read lines. In this case, each of the first read control lines is connected with multiple first read control terminals of multiple signal receiving circuits extending in the first direction in the corresponding one of the second signal receiving circuit groups; and each of the first data read lines is connected with multiple first data output terminals of the multiple signal receiving circuits extending in the second direction in the corresponding one of the first signal receiving circuit groups. Therefore, turn-on signals can be applied to multiple first read control terminals of multiple signal receiving circuits extending in the first direction in the corresponding one of the second signal receiving circuit groups through the first read control lines, so that reflected signals collected by the plurality of signal receiving circuits extending in the first direction in the corresponding second signal receiving circuit group can be simultaneously read through the plurality of first data read lines. In this case, the read reflected signals can be directly processed (e.g., weighted summation); and the turn-on signals can be applied to the first read control terminals of the plurality of signal receiving circuits extending along the first direction in the corresponding one of the second signal receiving circuit groups through the next first read control line to read the reflected signals collected by the plurality of signal receiving circuits extending along the first direction in the next second signal receiving circuit group. Therefore, the fingerprint identification circuit can achieve reading and processing at the same time, thereby improving the reading speed and processing speed and further greatly improving the fingerprint identification efficiency. In addition, through the above-mentioned process of reading and processing at the same time, the corresponding first signal receiving circuit group or second signal receiving circuit group can be flexibly and quickly read out, and the speed can be greatly increased in some applications such as non-square detection areas. FIG. 16 is only one example of a timing chart illustrating a driving method of the fingerprint identification circuit to achieve the receiving focusing function provided by the embodiment of the present disclosure. The receiving focusing function provided by the embodiment of the present disclosure is not limited to five first signal receiving circuit groups, and other number of first signal receiving circuit groups can also achieve the receiving focusing function.

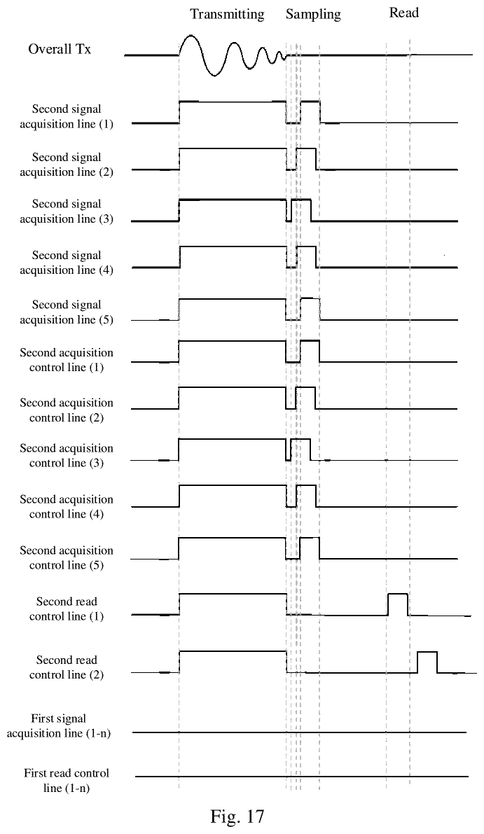

FIG. 17 is a timing chart of another driving method of the fingerprint identification circuit shown in FIG. 15; FIG. 17 is a timing chart of a driving method for driving a plurality of second signal receiving circuit groups arranged in the second direction to achieve a receiving focusing function. As illustrated by FIG. 17, similar to the receiving focusing function shown in FIG. 16, in the ultrasonic transmission stage, the reference voltage is applied to the second signal acquisition line and the second acquisition control line. In this case, the reference voltage on the first node can be used not only to transmit an ultrasonic wave with the driving voltage on the driving electrode of the ultrasonic sensor, but also for resetting. In the reflected signal acquisition stage, different second signal acquisition lines and second acquisition control lines are applied with acquisition signals with different time sequences to acquire reflected signals generated by ultrasonic sensors corresponding to the plurality of second signal receiving circuit groups arranged along a second direction. After the collection of the reflected signal is completed, turn-on signals are sequentially applied to the plurality of second read control lines, so that the reflected signals are read out through the plurality of second data read lines. In this case, each of the second read control lines is connected with multiple second read control terminals of the multiple signal receiving circuits extending along the second direction in the corresponding one of the first signal receiving circuit groups; and each of the second data read lines is connected with the multiple second data output terminals of the multiple signal receiving circuits extending along the first direction in the corresponding one of the second signal receiving circuit groups. Therefore, turn-on signals can be applied to multiple second read control terminals of the multiple signal receiving circuits extending along the second direction in the corresponding one of the first signal receiving circuit groups through the second read control lines, so that reflected signals collected by the plurality of signal receiving circuits extending along the second direction in the corresponding one of the first signal receiving circuit groups can be simultaneously read through the plurality of second data read lines. In this case, the read reflected signals can be directly processed (e.g., weighted summation); and the turn-on signals can be applied to the second read control terminals of the plurality of signal receiving circuits extending along the second direction in the corresponding one of the first signal receiving circuit groups through the next second read control line to read the reflected signals collected by the plurality of signal receiving circuits extending along the second direction in the next first signal receiving circuit group. Therefore, the fingerprint identification circuit can also achieve reading and processing while performing the receiving focusing function of a plurality of second signal receiving circuit groups arranged along the second direction, thereby improving the reading speed and processing speed and further greatly improving the fingerprint identification efficiency.

It should be noted that the fingerprint identification circuit shown in FIG. 15 can respectively achieve the receiving focusing function on a plurality of first receiving circuit groups arranged along the first direction and a plurality of second receiving circuit groups arranged along the second direction, and then process the fingerprint information obtained by the two operations to obtain more accurate fingerprint information. Therefore, the fingerprint identification circuit can achieve a two-dimensional receiving focusing function, thereby further improving the fingerprint identification performance In addition, because the fingerprint identification circuit is simultaneously provided with a first read control line, a first data read line, a second read control line, and a second data read line, the fingerprint identification circuit can achieve reading and processing while achieving receiving focusing functions on the plurality of first receiving circuit groups arranged along the first direction and the plurality of second receiving circuit groups arranged along the second direction respectively, thereby having higher fingerprint identification efficiency.

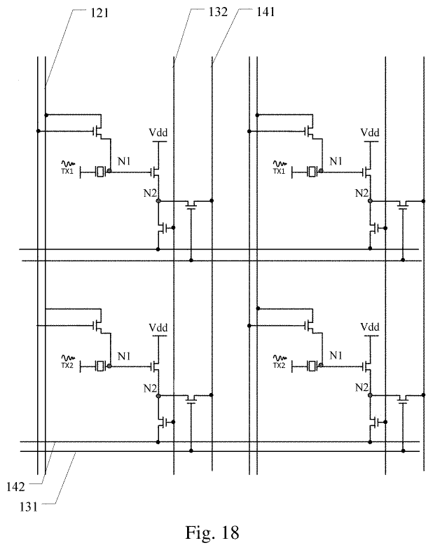

FIG. 18 is a schematic diagram of another fingerprint identification circuit according to an embodiment of the present disclosure. As illustrated by FIG. 18, the fingerprint identification circuit is only provided with a plurality of first signal acquisition lines 121 and a plurality of first acquisition control lines 151, and is not provided with a second signal acquisition line and a second acquisition control line. In addition, the fingerprint identification circuit is also provided with the above-mentioned first read control lines 131, the first data read lines 141, the second read control lines 132, and the second data read lines 142. The specific arrangement of the plurality of first signal acquisition lines 121, the plurality of first acquisition control lines 151, the plurality of first read control lines 131, the plurality of first data read lines 141, the plurality of second read control lines 132, and the plurality of second data read lines 142 can be seen in the relevant description of the previous embodiment, and will not be described here again. From this, it can be seen that the fingerprint identification circuit can achieve the receiving focusing functions on the plurality of first receiving circuit groups arranged along a first direction, and can also achieving reading and processing at the same time through the plurality of first read control lines and the plurality of first data read lines. The fingerprint identification circuit shown in FIG. 18 can be applied to a fingerprint identification module with transmitting focusing function. In this this case, the fingerprint identification circuit shown in FIG. 18 can not only achieve the receiving focusing function on the plurality of first signal receiving circuit groups arranged along the first direction, but also can apply turn-on signals to the plurality of signal receiving circuits arranged along the first direction in a corresponding one of the second signal receiving circuit groups through the second read control lines upon performing transmitting focusing of a plurality of ultrasonic sensor groups arranged along the second direction in the fingerprint identification module, and reading out reflected signals through the plurality of second data read lines to improve the signal read efficiency.

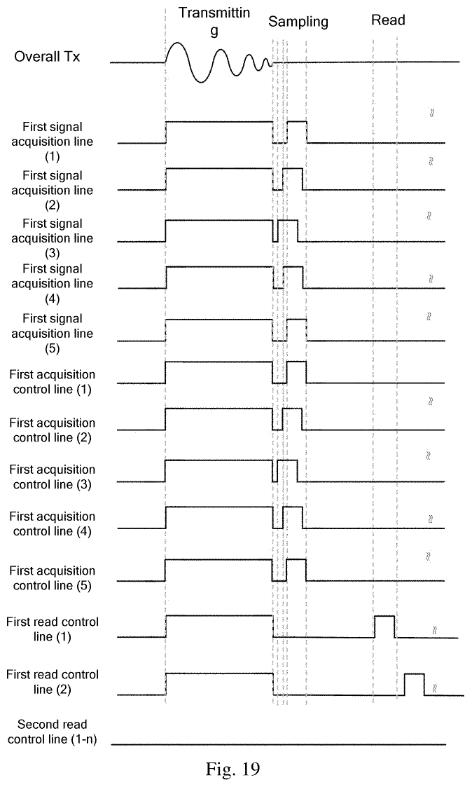

FIG. 19 is a timing chart of a driving method of the fingerprint identification circuit shown in FIG. 18; FIG. 19 is a timing chart of a driving method for driving a plurality of first signal receiving circuit groups (Rx1-Rx5) arranged in the first direction shown in FIG. 6 to achieve a receiving focusing function. As illustrated by FIG. 19, in the ultrasonic transmitting stage, both the first signal acquisition line and the first acquisition control line are applied with a reference voltage. In this case, the reference voltage on the first node can be used not only to transmit an ultrasonic wave with the driving voltage on the driving electrode of the ultrasonic sensor, but also for resetting. In the reflected signal acquisition stage, in order to acquire reflected signals of Rx1, Rx2, Rx3, Rx4 and Rx5, the first signal acquisition line and the first acquisition control line corresponding to Rx3 are applied with acquisition voltages at the first moment; the first signal acquisition lines and the first acquisition control lines corresponding to Rx2 and Rx4 are applied with acquisition signals at the second moment delayed from the first moment; and the first signal acquisition lines and the first acquisition control lines corresponding to Rx1 and Rx5 are applied with acquisition signals at the third moment delayed from the second moment. After the reflected signals are collected, turn-on signals are sequentially applied to the plurality of first read control lines to read the reflected signals through the plurality of first data read lines. In this case, each of the first read control lines is connected with multiple first read control terminals of the multiple signal receiving circuits extending in the first direction in the corresponding one of the second signal receiving circuit groups; and each of the first data read lines is connected with the first data output terminals of the plurality of signal receiving circuits extending in the second direction in the corresponding one of the first signal receiving circuit groups. Therefore, turn-on signals can be applied to multiple first read control terminals of the multiple signal receiving circuits extending in the first direction in the corresponding one of the second signal receiving circuit groups through the first read control lines, so that reflected signals collected by the plurality of signal receiving circuits extending in the first direction in the corresponding second signal receiving circuit group can be simultaneously read through the plurality of first data read lines. In this case, the read reflected signals can be directly processed (e.g., weighted summation); and the turn-on signals can be applied to the first read control terminals of the plurality of signal receiving circuits extending along the first direction in the corresponding one of the second signal receiving circuit groups through the next first read control line to read the reflected signals collected by the plurality of signal receiving circuits extending along the first direction in the next second signal receiving circuit group. Therefore, the fingerprint identification circuit can achieve reading and processing at the same time, thereby improving the reading speed and processing speed and further greatly improving the fingerprint identification efficiency. FIG. 19 is only one example of a timing chart illustrating a driving method of the fingerprint identification circuit to achieve the receiving focusing function provided by the embodiment of the present disclosure. The receiving focusing function provided by the embodiment of the present disclosure is not limited to five first signal receiving circuit groups, and other number of first signal receiving circuit groups can also achieve the receiving focusing function.

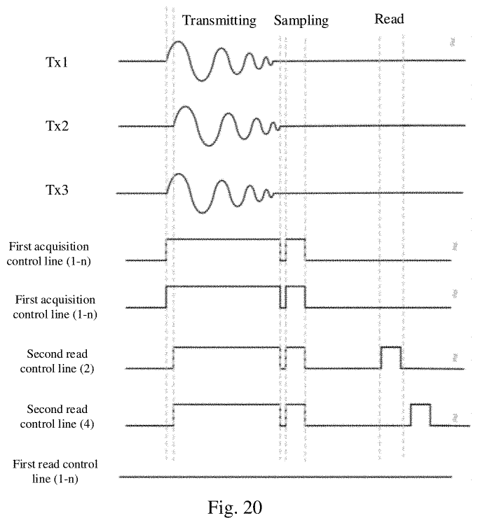

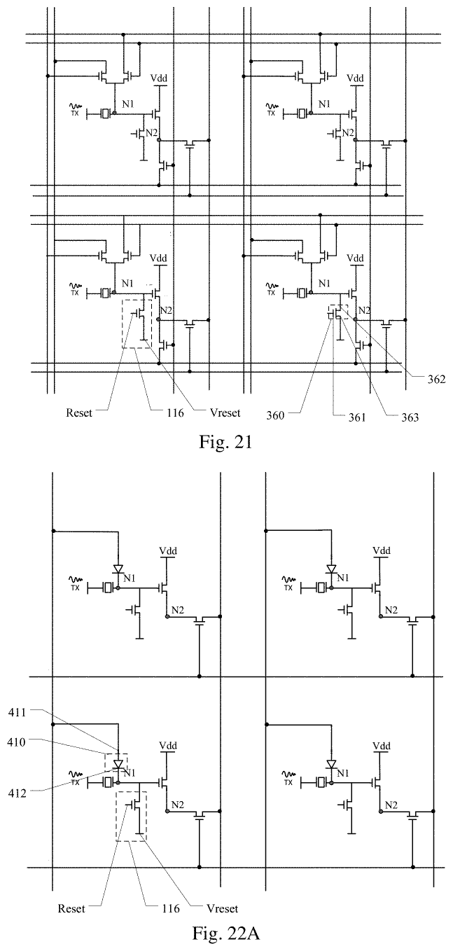

FIG. 20 is a timing chart of another driving method of the fingerprint identification circuit shown in FIG. 18; FIG. 20 is a timing chart of a driving method for driving the plurality of second ultrasonic sensor groups arranged in the second direction shown in FIG. 9 to achieve the transmitting focusing function. As illustrated by FIG. 20, in the ultrasonic transmission stage, driving voltages are applied to Tx1 and Tx3 at the fourth moment and then to Tx2 at the fifth moment, so that ultrasonic focusing can be achieved at the position corresponding to Tx2 (directly above Tx2). All the first signal acquisition lines and the first acquisition control lines are applied with reference voltages. In this case, the reference voltage on the first node can be used not only for transmitting an ultrasonic wave with the driving voltage on the driving electrode of the ultrasonic sensor, but also for resetting. In the reflected signal acquisition stage, all the first signal acquisition lines and the first acquisition control lines are applied with acquisition signals to acquire reflected signals. After the collection of the reflected signal is completed, the turn-on signals is only applied to the second read control line corresponding to the ultrasonic focusing position, so that only the reflected signals of the second ultrasonic sensor group corresponding to the enhanced position is read out by the ultrasonic wave, thereby improving the signal read efficiency.

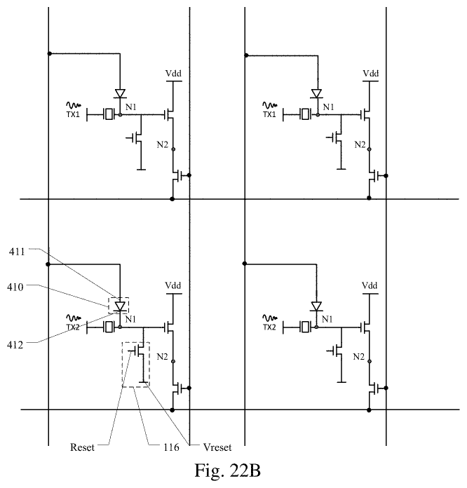

FIG. 21 is a schematic diagram of another fingerprint identification circuit according to an embodiment of the present disclosure. As illustrated by FIG. 21, different from the fingerprint identification circuit shown in FIG. 15, each of the signal receiving circuits 110 further includes a reset sub-circuit 116 including a sixth thin film transistor 360; the sixth thin film transistor 360 includes a sixth gate electrode 361, a sixth source electrode 362, and a sixth drain electrode 363; the sixth gate electrode 361 is connected with a reset control line Reset, the sixth source electrode 162 is connected with the reset voltage source Vreset, and the sixth drain electrode 363 is connected to the first node N1. For example, the reset control line Reset can be simultaneously connected with the sixth gate electrodes of all signal receiving circuits in the fingerprint identification circuit, so that the reset signals can be applied to the sixth gate electrodes of all signal receiving circuits in the fingerprint identification circuit through the reset control line Reset, thereby achieving reset. In this case, the first signal acquisition line or the second signal acquisition line may not be applied with a reference voltage at the ultrasonic transmitting stage, thus simplifying the timing control of the first signal acquisition line or the second signal acquisition line, and further simplifying the control circuit for controlling the first signal acquisition line or the second signal acquisition line. In addition, the first thin film transistor or the fourth thin film transistor is only used for loading acquisition signals, with no reference voltage or reset voltage loaded, so that the stability of the first thin film transistor or the fourth thin film transistor is better.

FIG. 22A is a schematic diagram of another fingerprint identification circuit provided by an embodiment of the present disclosure; FIG. 22B is a schematic diagram of another fingerprint identification circuit provided by an embodiment of the present disclosure. As illustrated by FIG. 22A, different form the fingerprint identification circuit provided in FIG. 5, the acquisition sub-circuit 112 in each of the signal receiving circuits 110 adopts a diode instead of a thin film transistor. In this case, the acquisition sub-circuit 112 includes a first diode 410 and the reset sub-circuit 116. The first diode 410 includes a first anode 411 and a first cathode 412; the first signal acquisition line 121 is connected with the first anode 411; the first cathode 412 is connected to the first node N1; the first anode 411 is the first acquisition signal input terminal 1121; and the first cathode 412 is the first acquisition signal output terminal 1123. As illustrated by FIG. 22B, different from the fingerprint identification circuit provided in FIG. 8, the acquisition sub-circuit 112 in each of the signal receiving circuits 110 adopts a diode instead of a thin film transistor. In this case, the acquisition sub-circuit 112 includes a first diode 410 and the above-mentioned reset sub-circuit 116. The first diode 410 includes a first anode 411 and a first cathode 412. The first signal acquisition line 121 is connected with the first anode 411; the first cathode 412 is connected to the first node N1; the first anode 411 is the first acquisition signal input terminal 1121; and the first cathode 412 is the first acquisition signal output terminal 1123. Therefore, the fingerprint identification circuit may not be provided with the first acquisition control line, thus simplifying the circuit structure.

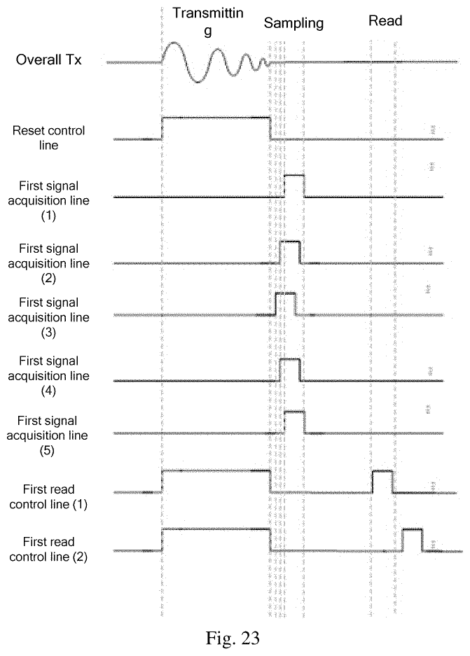

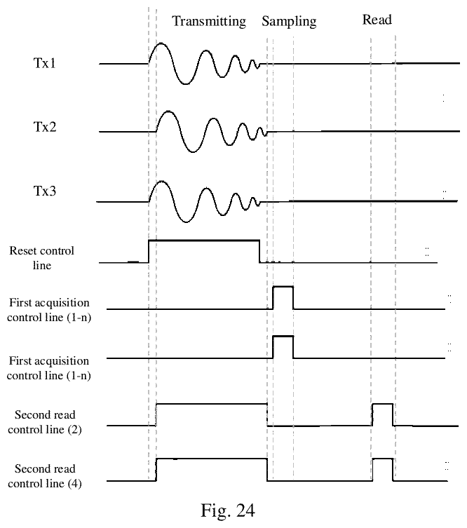

FIG. 23 is a timing chart of a driving method of the fingerprint identification circuit shown in FIG. 22A; FIG. 23 is a timing chart of a driving method for driving a plurality of first signal receiving circuit groups (Rx1-Rx5) arranged in the first direction shown in FIG. 6 to achieve a receiving focusing function. As illustrated by FIG. 23, in the ultrasonic transmitting stage, the reset control line Reset is applied with a reference voltage. In this case, the reference voltage on the first node can be used not only to transmit an ultrasonic wave with the driving voltage on the driving electrode of the ultrasonic sensor, but also for resetting. In the reflected signal acquisition stage, in order to acquire reflected signals of Rx1, Rx2, Rx3, Rx4 and Rx5, the first signal acquisition line corresponding to Rx3 is applied with an acquisition voltage at the first moment; the first signal acquisition lines corresponding to Rx2 and Rx4 are applied with acquisition signals at the second moment delayed from the first moment; and the first signal acquisition lines corresponding to Rx1 and Rx5 are applied with acquisition signals at the third moment delayed from the second moment. After the collection of the reflected signal is completed, turn-on signals are sequentially applied to the plurality of second read control lines, so that the reflected signals are read out through the plurality of second data read lines. Finally, the weighted summation of these reflected signals can be performed to achieve the receiving focusing function on the plurality of first signal receiving circuit groups arranged along the first direction.

FIG. 24 is a timing chart of another driving method of the fingerprint identification circuit shown in FIG. 22B; FIG. 24 is a timing chart of a driving method for driving the plurality of second ultrasonic sensor groups arranged in the second direction shown in FIG. 9 to achieve the transmitting focusing function. As illustrated by FIG. 24, in the ultrasonic wave transmission stage, driving voltages are applied to Tx1 and Tx3 at the fourth moment, and then driving voltages are applied to Tx2 at the fifth moment, so that ultrasonic wave focusing can be achieved at the position corresponding to Tx2 (directly above Tx2). In this case, the reset control line Reset is applied with a reference voltage; in this case, the reference voltage on the first node can be used not only to transmit an ultrasonic wave with the driving voltage on the driving electrode of the ultrasonic sensor, but also for resetting. In the reflected signal acquisition stage, all the first signal acquisition lines are applied with acquisition signals to acquire reflected signals. After the collection of the reflected signal is completed, the turn-on signal is only applied to the second read control line corresponding to the ultrasonic focusing position, so that only the reflected signal of the second ultrasonic sensor group corresponding to the enhanced position is read out by the ultrasonic wave, thereby improving the signal read efficiency.

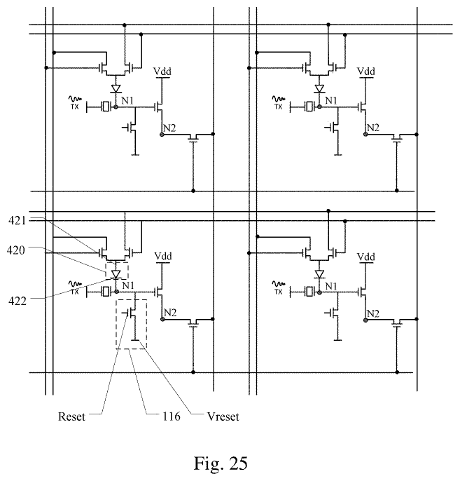

FIG. 25 is a schematic diagram of another fingerprint identification circuit according to an embodiment of the present disclosure. As illustrated by FIG. 25, different from the fingerprint identification circuit shown in FIG. 12, the acquisition sub-circuit 112 in each of the signal receiving circuit 110 further includes a second diode 420, each of the signal receiving circuits 110 includes the reset sub-circuit 116 described above; the second diode 420 includes a second anode 421 and a second cathode 422; the first drain electrode 313 and the fourth drain electrode 343 are connected with the second anode 421; and the second cathode 422 is connected to the first node N1. Therefore, the first thin film transistor and the second thin film transistor in the fingerprint identification circuit only function as switches.

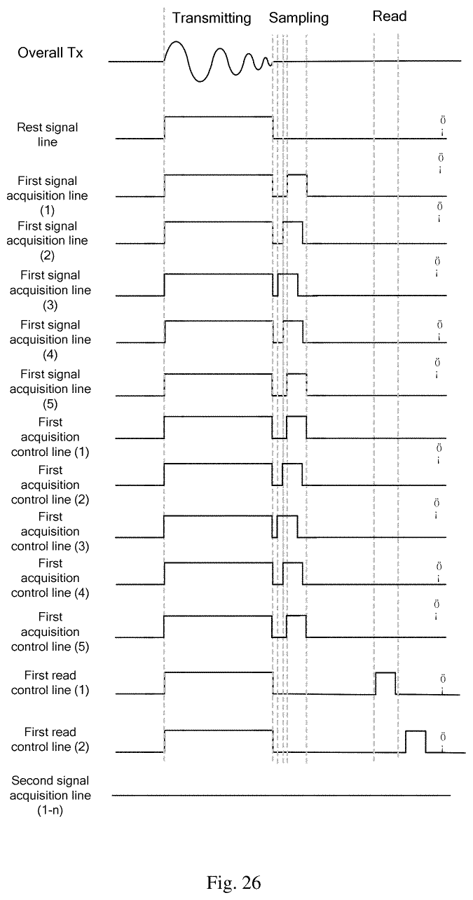

FIG. 26 is a timing chart of a driving method of the fingerprint identification circuit shown in FIG. 25; FIG. 26 is a timing chart of a driving method for driving a plurality of first signal receiving circuit groups (Rx1-Rx5) arranged in the first direction shown in FIG. 6 to achieve a receiving focusing function. As illustrated by FIG. 26, in the ultrasonic transmitting stage, the reset control line Reset is applied with a reference voltage. In this case, the reference voltage on the first node can be used not only to transmit an ultrasonic wave with the driving voltage on the driving electrode of the ultrasonic sensor, but also for resetting. In the reflected signal acquisition stage, in order to acquire reflected signals of Rx1, Rx2, Rx3, Rx4 and Rx5, the first signal acquisition line corresponding to Rx3 is applied with an acquisition voltage at the first moment; the first acquisition control line corresponding to Rx3 is applied with a turn-on signal at the first moment; the first signal acquisition lines corresponding to Rx2 and Rx4 are applied with acquisition signals at the second moment delayed from the first moment; the first acquisition control lines corresponding to Rx2 and Rx4 are applied with turn-on signals at the second moment; the first signal acquisition lines corresponding to Rx1 and Rx5 are applied with acquisition signals at the third moment delayed from the second moment; and the first acquisition control lines corresponding to Rx1 and Rx5 are applied with turn-on signals at the third moment. After the collection of the reflected signal is completed, turn-on signals are sequentially applied to the plurality of second read control lines, so that the reflected signals are read out through the plurality of second data read lines. Finally, the weighted summation of these reflected signals can be performed to achieve the receiving focusing function on a plurality of first signal receiving circuit groups arranged along the first direction. It should be noted that the above-mentioned turn-on signals and the above-mentioned acquisition signals are the same in timing, and the above-mentioned turn-on signals and the above-mentioned acquisition signals can be different in voltage.

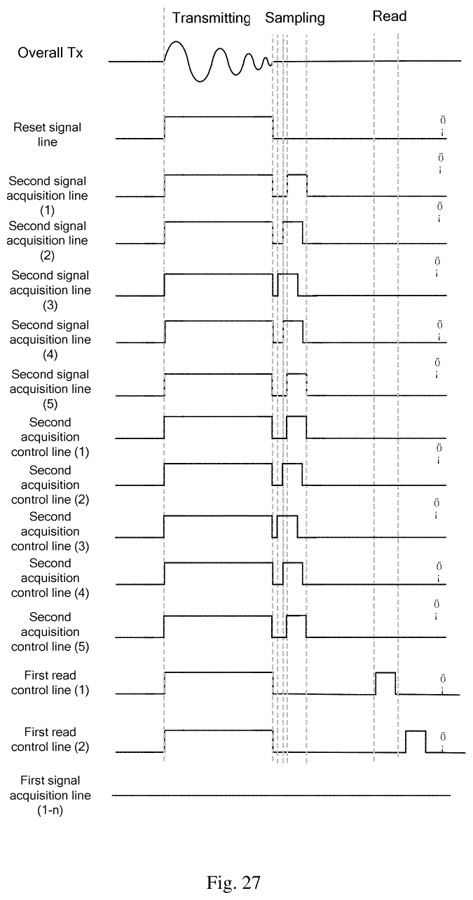

FIG. 27 is a timing chart of another driving method of the fingerprint identification circuit shown in FIG. 26; FIG. 27 is a timing chart of a driving method for driving a plurality of second signal receiving circuit groups arranged in the second direction to achieve a receiving focusing function. Similar to the driving method shown in FIG. 26, in the ultrasonic transmitting stage, the reset control line Reset is applied with a reference voltage. In this case, the reference voltage on the first node can be used not only to transmit an ultrasonic wave with the driving voltage on the driving electrode of the ultrasonic sensor, but also for resetting. In the reflected signal acquisition stage, in order to acquire reflected signals of the plurality of second signal receiving circuit groups arranged in the second direction, the second signal acquisition lines are applied with acquisition signals with different timings to the plurality of second signal receiving circuit groups arranged in the second direction; and the second signal control line is applied with turn-on signals with different timings to the plurality of second signal receiving circuit groups arranged in the second direction. After the collection of the reflected signal is completed, turn-on signals are sequentially applied to the plurality of second read control lines, so that the reflected signals are read out through the plurality of second data read lines. Finally, the weighted summation of these reflected signals can be performed to achieve the receiving focusing function on the plurality of first signal receiving circuit groups arranged along the first direction. It should be noted that the above-mentioned turn-on signals and the above-mentioned acquisition signals are the same in timing; and the above-mentioned turn-on signals and the above-mentioned acquisition signals can be different in voltage.

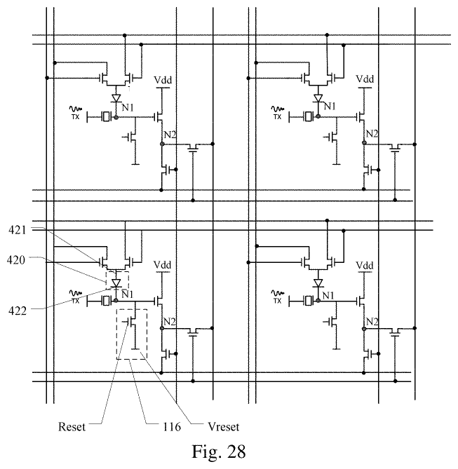

FIG. 28 is a schematic diagram of another fingerprint identification circuit according to an embodiment of the present disclosure. As illustrated by FIG. 28, different from the fingerprint identification circuit shown in FIG. 15, the acquisition sub-circuit 112 in each of the signal receiving circuits 110 further includes a second diode 420; each of the signal receiving circuits 110 includes the reset sub-circuit 116 described above; the second diode 420 includes a second anode 421 and a second cathode 422; the first drain electrode 313 and the fourth drain electrode 343 are connected with the second anode 421; and the second cathode 422 is connected to the first node N1. Therefore, the first thin film transistor and the second thin film transistor in the fingerprint identification circuit only function as switches.

In addition, as illustrated by FIG. 28, the fingerprint identification circuit is simultaneously provided with the above-mentioned plurality of first read control lines 131, the plurality of first data read lines 141, the plurality of second read control lines 132, and the plurality of second data read lines 142. The specific arrangement of the plurality of first read control lines 131, the plurality of first data read lines 141, the plurality of second read control lines 132, and the plurality of second data read lines 142 can be seen in the related description of the previous embodiment, and will not be repeated here.

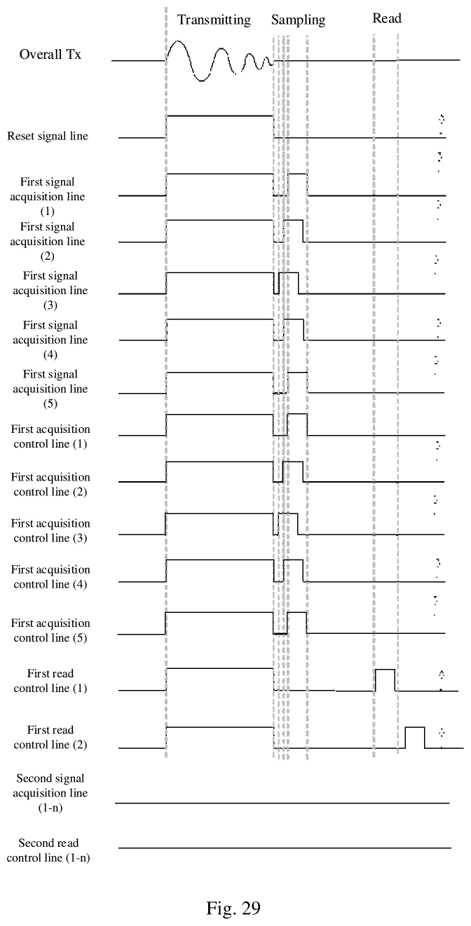

FIG. 29 is a timing chart of a driving method of the fingerprint identification circuit shown in FIG. 28; FIG. 29 is a timing chart of a driving method for driving a plurality of first signal receiving circuit groups (Rx1-Rx5) arranged in the first direction shown in FIG. 6 to achieve a receiving focusing function. As illustrated by FIG. 29, in the ultrasonic transmitting stage, the reset control line Reset is applied with a reference voltage; in this case, the reference voltage on the first node can be used not only to transmit an ultrasonic wave with the driving voltage on the driving electrode of the ultrasonic sensor, but also for resetting. In the reflected signal acquisition stage, in the reflected signal acquisition stage, in order to acquire reflected signals of Rx1, Rx2, Rx3, Rx4 and Rx5, the first signal acquisition line corresponding to Rx3 is applied with an acquisition voltage at the first moment, the first acquisition control line corresponding to Rx3 is applied with a turn-on signal at the first moment, the first signal acquisition lines corresponding to Rx2 and Rx4 are applied with acquisition signals at the second moment delayed from the first moment; the first acquisition control lines corresponding to Rx2 and Rx4 are applied with turn-on signals at the second moment; the first signal acquisition lines corresponding to Rx1 and Rx5 are applied with acquisition signals at the third moment delayed from the second moment; and the first acquisition control lines corresponding to Rx1 and Rx5 are applied with turn-on signals at the third moment. After the reflected signal is collected, turn-on signals are sequentially applied to the plurality of first read control lines to read the reflected signals through the plurality of first data read lines. In this case, each of the first read control lines is connected with multiple first read control terminals of the multiple signal receiving circuits extending in the first direction in the corresponding one of the second signal receiving circuit groups; each of the first data read lines is connected with multiple first data output terminals of the multiple signal receiving circuits extending in the second direction in the corresponding one of the first signal receiving circuit groups. Therefore, turn-on signals can be applied to multiple first read control terminals of multiple signal receiving circuits extending in the first direction in the corresponding one of the second signal receiving circuit groups through the first read control lines, so that reflected signals collected by the plurality of signal receiving circuits extending in the first direction in the corresponding one of the second signal receiving circuit groups can be simultaneously read through the plurality of first data read lines; in this case, the read reflected signals can be directly processed (e.g., weighted summation) and the turn-on signals can be applied to the first read control terminals of the plurality of signal receiving circuits extending along the first direction in the corresponding one of the second signal receiving circuit groups through the next first read control line to read the reflected signals collected by the plurality of signal receiving circuits extending along the first direction in the next second signal receiving circuit group. Therefore, the fingerprint identification circuit can achieve reading and processing at the same time, thereby improving the reading speed and processing speed and further greatly improving the fingerprint identification efficiency. FIG. 29 is only one example of a timing chart illustrating a driving method of the fingerprint identification circuit to achieve the receiving focusing function provided by the embodiment of the present disclosure. The receiving focusing function provided by the embodiment of the present disclosure is not limited to five first signal receiving circuit groups, and other number of first signal receiving circuit groups can also achieve the receiving focusing function.

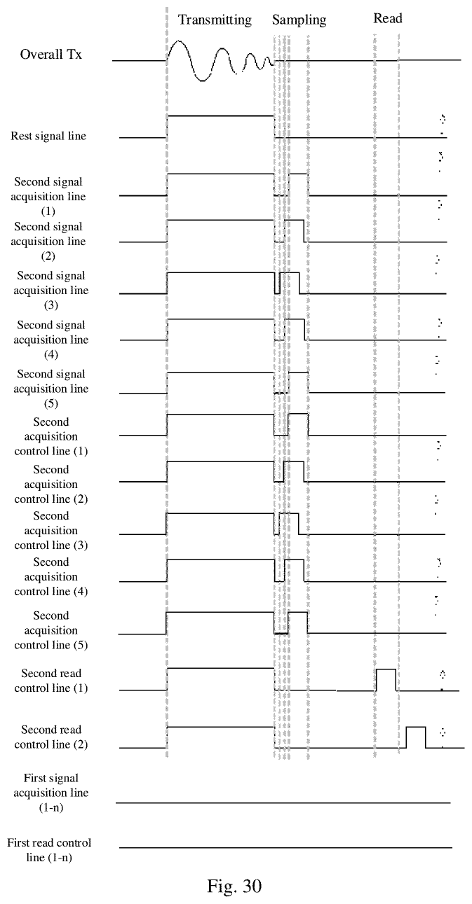

FIG. 30 is a timing chart of another driving method of the fingerprint identification circuit shown in FIG. 28; FIG. 30 is a timing chart of a driving method for driving a plurality of second signal receiving circuit groups arranged in the second direction to achieve a receiving focusing function. As illustrated by FIG. 30, similar to the receiving focusing function shown in FIG. 29, in the ultrasonic transmitting stage, the reset control line Reset is applied with a reference voltage; and in this case, the reference voltage on the first node can be used not only to transmit an ultrasonic wave with the driving voltage on the driving electrode of the ultrasonic sensor, but also for resetting. In the reflected signal acquisition stage, to acquire reflected signals of the plurality of second signal receiving circuit groups arranged in the second direction, the second signal acquisition lines are applied with acquisition signals with different timings to the plurality of second signal receiving circuit groups arranged in the second direction; and the second signal control lines are applied with turn-on signals with different timings to the plurality of second signal receiving circuit groups arranged in the second direction. After the collection of the reflected signals is completed, turn-on signals are sequentially applied to the plurality of second read control lines, so that the reflected signals are read out through the plurality of second data read lines. In this case, each of the second read control lines is connected with the second read control terminals of the plurality of signal receiving circuits extending along the second direction in the corresponding first signal receiving circuit group; each of the second data read lines is connected with multiple second data output terminals of the multiple signal receiving circuits extending along the first direction in the corresponding one of the second signal receiving circuit groups. Therefore, turn-on signals can be applied to the multiple second read control terminals of the multiple signal receiving circuits extending along the second direction in the corresponding one of the first signal receiving circuit groups through the second read control lines, so that reflected signals collected by the plurality of signal receiving circuits extending along the second direction in the corresponding first signal receiving circuit group can be simultaneously read through the plurality of second data read lines; in this case, the read reflected signals can be directly processed (e.g., weighted summation); and the turn-on signals can be applied to the second read control terminals of the plurality of signal receiving circuits extending along the second direction in the corresponding one of the first signal receiving circuit groups through the next second read control line to read the reflected signals collected by the plurality of signal receiving circuits extending along the second direction in the next first signal receiving circuit group. Therefore, the fingerprint identification circuit can also achieve reading and processing while performing the receiving focusing function of the plurality of second signal receiving circuit groups arranged along the second direction, thereby improving the reading speed and processing speed and further greatly improving the fingerprint identification efficiency.

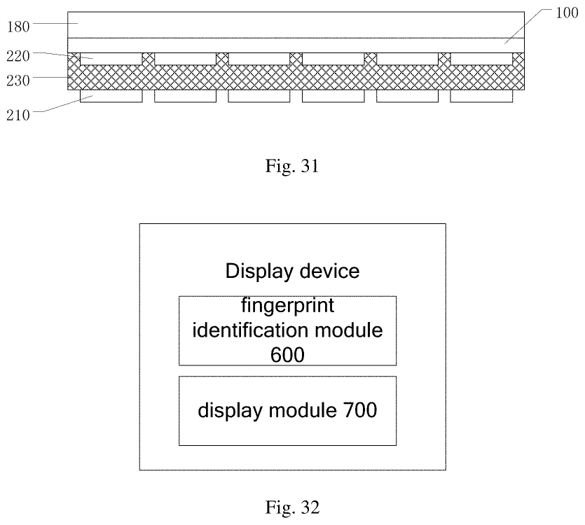

An embodiment of the present disclosure provides a fingerprint identification module. FIG. 31 is a schematic diagram of a fingerprint identification module according to an embodiment of the present disclosure. As illustrated by FIG. 31, the fingerprint identification module includes the fingerprint identification circuit 100 described above. Therefore, the fingerprint identification module has the same or corresponding beneficial technical effects as the above-mentioned fingerprint identification circuit 100. For details, please refer to the relevant description of the above-mentioned embodiments, which will not be repeated here.

In some examples, as illustrated by FIG. 31, the fingerprint identification module further includes a base substrate 180 in which the fingerprint identification circuit 100 described above can be disposed.

In some examples, as illustrated by FIG. 31, the fingerprint identification module includes a plurality of ultrasonic sensors 200. Each of the ultrasonic sensors 200 includes a transmitting electrode 210, a receiving electrode 220, and a piezoelectric material layer 230 located between the transmitting electrode 210 and the receiving electrode 220. The plurality of ultrasonic sensors 200 are arranged in one-to-one correspondence with the plurality of signal receiving circuits 110, and the first node N1 of each of the signal receiving circuits 110 is connected with the receiving electrode 220 of a corresponding one of the ultrasonic sensors 200.

For example, the material of the driving electrode 210 includes one or more of copper, silver, and aluminum.

In some examples, the fingerprint identification module can be a fingerprint identification module having a transmitting focusing function. As illustrated by FIG. 9, the plurality of ultrasonic sensors 200 are arranged in an array along the first direction and the second direction to form a plurality of first ultrasonic sensor groups 2001 arranged in the first direction and a plurality of second ultrasonic sensor groups 2002 arranged in the second direction. Transmitting electrodes 220 of multiple ultrasonic sensors 200 arranged in the second direction in each of the first ultrasonic sensor groups 2001 are different, and multiple ultrasonic sensors 200 arranged in the first direction in each of the second ultrasonic sensor groups 2002 share one transmitting electrode 220 having a strip shape. Therefore, the fingerprint identification module can achieve the transmitting focusing function by applying driving voltages with different timings to different transmitting electrodes 220 having strip shapes. In this case, the ultrasonic wave at a position corresponding to a specific second ultrasonic sensor group in the fingerprint identification module is enhanced. Upon the fingerprint identification module improving the intensity or energy of the ultrasonic wave as transmitted in a specific region or a specific direction by achieving the transmitting focusing of the ultrasonic wave, the fingerprint identification module can not only achieve fingerprint identification, but also penetrate the finger to distinguish whether the fingerprint is real skin.

An embodiment of the present disclosure also provides a driving method of a fingerprint identification circuit. The fingerprint identification circuit can be the fingerprint identification circuit provided in the above embodiments. The driving method includes: dividing a plurality of first signal acquisition lines into N first signal acquisition line groups, each of the first signal acquisition line groups includes at least two first signal acquisition lines; after the ultrasonic sensor transmits an ultrasonic wave, according to an arrival time of reflected echo, at least two first signal acquisition lines in each of the first signal acquisition line groups apply acquisition signals to multiple first acquisition signal input terminals of the multiple signal receiving circuits arranged along the second direction in a corresponding one of the first signal receiving circuit groups at different time points to receive the reflected echo; and performing weighted summation on data output by multiple first data output terminals of the first signal receiving circuit groups corresponding to the at least two first acquisition signal lines to obtain first fingerprint information, wherein N is a positive integer greater than or equal to 1.

In the driving method of the fingerprint identification circuit provided by the present embodiment, upon the ultrasonic wave transmitted by the ultrasonic sensor being reflected by a finger, the reflected echo reaches the first signal receiving circuit groups arranged along the first direction at different times; the at least two first signal acquisition lines in the first signal acquisition line group apply acquisition signals to the first acquisition signal input terminals of the multiple signal receiving circuits arranged along the second direction in the corresponding one of the first signal receiving circuit groups at different time points to receive the reflected echo; and by performing weighted summation on data output from the first data output terminals of the first signal receiving circuit groups corresponding to the at least two first acquisition signal lines, the receiving focusing function of the plurality of first signal receiving circuit groups arranged along the first direction can be achieved, so that first fingerprint information with higher intensity and higher signal-to-noise ratio can be obtained; and the fingerprint identification performance can be further improved. It should be noted that the above-mentioned different time points can be calculated according to the distance between the first signal receiving circuit group and reflective positions on the finger and the speed of ultrasonic wave, and details can refer to the related description of FIG. 6.

In some examples, the fingerprint identification circuit further includes a plurality of first read control lines and a plurality of first data read lines; each of the first read control lines extends in the first direction, and the plurality of first read control lines are arranged in the second direction; each of the first data read lines extends along the second direction, the plurality of first data read lines are arranged along the first direction; the plurality of first read control lines are arranged in one-to-one correspondence with the plurality of second signal receiving circuit groups; the plurality of first data read lines are arranged in one-to-one correspondence with the plurality of first signal receiving circuit groups; each of the first read control lines is connected with multiple first read control terminals of multiple signal receiving circuits extending along the first direction in a corresponding one of the second signal receiving circuit groups; each of the first read control lines is connected with multiple first data output terminals of multiple signal receiving circuits extending along the second direction in a corresponding one of the first signal receiving circuit groups; and the driving method further includes: after the plurality of first signal receiving lines send acquisition signals, applying turn-on signals to the multiple first read control terminals of the multiple signal receiving circuits extending along the first direction in the corresponding one of the second signal receiving circuit groups through the plurality of first read control lines respectively.

In the driving method provided by this example, after the plurality of first signal acquisition lines send acquisition signals, turn-on signals are applied to the multiple first read control terminals of the multiple signal receiving circuits extending along the first direction in the corresponding one of the second signal receiving circuit groups through the plurality of first read control lines respectively. Therefore, reflected signals collected by the multiple signal receiving circuits extending along the first direction in the corresponding one of the second signal receiving circuit groups can be simultaneously read out through the plurality of first data read lines; in this case, the read reflected signals can be directly processed (e.g., weighted summation); and turn-on signals can be applied to the multiple first read control terminals of the multiple signal receiving circuits extending along the first direction in the corresponding one of the second signal receiving circuit groups through a next first read control line to read reflected signals collected by multiple signal receiving circuits extending along the first direction in a next second signal receiving circuit group. Therefore, the fingerprint identification circuit can achieve reading and processing at the same time, thereby improving the reading speed and processing speed and further greatly improving the fingerprint identification efficiency.

In some examples, the fingerprint identification circuit further includes a plurality of second signal acquisition lines; each of the second signal acquisition lines extends along the first direction; the plurality of second signal acquisition lines are arranged along the second direction; the acquisition sub-circuit further includes a second acquisition signal input terminal and a second acquisition signal output terminal; the second acquisition signal output terminal is connected to the first node, the plurality of second signal acquisition lines are arranged in one-to-one correspondence with the plurality of second signal receiving circuit groups, each of the second signal acquisition lines is connected with multiple second acquisition signal input terminals of multiple signal receiving circuits arranged along the first direction in a corresponding one of the second signal receiving circuit groups; and the driving method further includes: dividing the plurality of second signal acquisition lines into M second signal acquisition line groups, each of the second signal acquisition line groups includes at least two second signal acquisition lines; after the ultrasonic sensor transmits an ultrasonic wave, according to an arrival time of reflected echo, the at least two second signal acquisition lines in each of the second signal acquisition line groups apply acquisition signals to the multiple second acquisition signal input terminals of the multiple signal receiving circuits arranged along a first direction in the corresponding one of the second signal receiving circuit groups at different time points to receive reflected echo; and performing weighted summation on data output by the multiple second data output terminals of the second signal receiving circuit groups corresponding to the at least two second acquisition signal lines to obtain second fingerprint information, wherein M is a positive integer greater than or equal to 1.

In the driving method provided by this example, upon the ultrasonic wave transmitted by the ultrasonic sensor being reflected by the finger, the reflected echo reaches the second signal receiving circuit groups arranged in the second direction at different times, the at least two second signal acquisition lines in the second signal acquisition line group apply acquisition signals to the multiple second acquisition signal input terminals of the multiple signal receiving circuits arranged in the first direction in the corresponding one of the second signal receiving circuit groups at different time points to receive the reflected echo, and the receiving focusing functions of the multiple second signal receiving circuit groups arranged along the second direction can be achieved by performing weighted summation on data output from the second data output terminals of the second signal receiving circuit groups corresponding to the at least two second acquisition signal lines, so that fingerprint data with higher intensity and higher signal-to-noise ratio can be obtained, and fingerprint identification performance can be further improved. In addition, the driving method achieves the receiving focusing function on multiple first receiving circuit groups arranged along the first direction and multiple second receiving circuit groups arranged along the second direction respectively, so that second fingerprint information with higher intensity and higher signal-to-noise ratio can be obtained.

In some examples, the driving method further includes: processing the first fingerprint information and the second fingerprint information to obtain third fingerprint information. Therefore, by processing the fingerprint information obtained by two operations, more accurate fingerprint information can be obtained. Therefore, the fingerprint identification circuit can achieve a two-dimensional receiving focusing function, thereby further improving the fingerprint identification performance.

In some examples, the fingerprint identification circuit further includes a plurality of second read control lines and a plurality of second data read lines; each of the second read control lines extends in a second direction; and the plurality of second read control lines are arranged in the first direction; each of the second data read lines extends along the first direction; the plurality of second data read lines are arranged along the second direction. The output sub-circuit includes a second read control terminal and a second data output terminal; the plurality of second read control lines are arranged in one-to-one correspondence with the plurality of first signal receiving circuit groups; the plurality of second data read lines are arranged in one-to-one correspondence with the plurality of second signal receiving circuit groups; each of the second read control lines is connected with multiple second read control terminals of multiple signal receiving circuits extending along the second direction in a corresponding one of the first signal receiving circuit groups; each of the second read control lines is connected with multiple second data output terminals of multiple signal receiving circuits extending along the first direction in a corresponding one of the second signal receiving circuit groups; and the driving method further includes: after the plurality of second signal acquisition lines send the acquisition signals, applying turn-on signals to the multiple second read control terminals of the multiple signal receiving circuits extending along the second direction in the corresponding one of the first signal receiving circuit groups through the plurality of second read control lines respectively.

In the driving method provided by this example, after the plurality of second signal acquisition lines send acquisition signals, turn-on signals are applied to the multiple second read control terminals of the multiple signal receiving circuits extending in the first direction in the corresponding one of the first signal receiving circuit groups through the plurality of second read control lines respectively. Therefore, reflected signals collected by the plurality of signal receiving circuits extending along the second direction in the corresponding one of the first signal receiving circuit groups can be simultaneously read out through the plurality of second data read lines; and in this case, the read reflected signals can be directly processed (e.g., weighted summation); and turn-on signals can be applied to the multiple second read control terminals of the multiple signal receiving circuits extending along the second direction in the corresponding one of the first signal receiving circuit groups through a next second read control line to read reflected signals collected by the plurality of signal receiving circuits extending along the second direction in a next first signal receiving circuit group. Therefore, the fingerprint identification circuit can achieve reading and processing at the same time, thereby improving the reading speed and processing speed and further greatly improving the fingerprint identification efficiency. In addition, the driving method of the fingerprint identification circuit can achieving reading and processing while achieving the receiving focusing functions on the multiple first receiving circuit groups arranged along the first direction and the multiple second receiving circuit groups arranged along the second direction respectively, thereby having higher fingerprint identification efficiency.

An embodiment of the present disclosure also provides a display device. FIG. 32 is a schematic diagram of a display device provided according to an embodiment of the present disclosure. The display device includes the fingerprint identification module 600 provided in the above embodiments. Therefore, the display device has the same or corresponding beneficial technical effects as the fingerprint identification module 600 described above. Details can refer to the relevant description of the above embodiment, which will not be repeated here.

For example, in some examples, as illustrated by FIG. 32, the display device further includes a display module 700, the area of which is approximately the same as that of the fingerprint identification module 600, so that full-screen fingerprint identification can be achieved. In this case, the fingerprint identification module can also achieve a touch function, so that no additional touch devices, such as a capacitive touch panel, need to be provided, thus reducing the cost of the display device. Of course, the embodiment of the present disclosure includes but is not limited thereto. The area of the display module and the area of the fingerprint identification module may not be equal, and the fingerprint identification module may only be arranged in a region where fingerprint identification is required.

For example, the display device can be an electronic device with a display function such as a television, a mobile phone, a computer, a notebook computer, an electronic photo album, a navigator and the like.

The following statements should be noted:

(1) The accompanying drawings involve only the structure(s) in connection with the embodiment(s) of the present disclosure, and other structure(s) can be referred to common design(s).

(2) In case of no conflict, features in one embodiment or in different embodiments can be combined.

What have been described above are only specific implementations of the present disclosure, the protection scope of the present disclosure is not limited thereto. Any changes or substitutions easily occur to those skilled in the art within the technical scope of the present disclosure should be covered in the protection scope of the present disclosure. Therefore, the protection scope of the present disclosure should be based on the protection scope of the claims.

1. A fingerprint identification circuit, comprising:
a plurality of signal receiving circuits, arranged in an array along a first direction and a second direction to form a plurality of first signal receiving circuit groups arranged along the first direction and extending along the second direction and a plurality of second signal receiving circuit groups arranged along the second direction and extending along the first direction; and
a plurality of first signal acquisition lines, each of the first signal acquisition lines extending along the second direction, the plurality of first signal acquisition lines arranged along the first direction,
wherein each of the signal receiving circuits comprises an acquisition sub-circuit and an output sub-circuit, the acquisition sub-circuit comprises a first acquisition signal input terminal and a first acquisition signal output terminal, the output sub-circuit comprises a first read control terminal, a first data output terminal, and a data input terminal, the first acquisition signal output terminal and the data input terminal are connected to a first node, the first node is configured to be connected with a receiving electrode of an ultrasonic sensor,
the plurality of first signal acquisition lines are arranged in one-to-one correspondence with the plurality of first signal receiving circuit groups, and each of the first signal acquisition lines is connected with multiple first acquisition signal input terminals of multiple signal receiving circuits arranged along the second direction in a corresponding one of the plurality of first signal receiving circuit groups.

2. The fingerprint identification circuit according to claim 1, further comprising:
a plurality of first read control lines, each of the first read control lines extending along the first direction, and the plurality of first read control lines arranged along the second direction; and
a plurality of first data read lines, each of the first data read lines extending along the second direction, the plurality of first data read lines arranged along the first direction,
wherein the plurality of first read control lines and the plurality of second signal receiving circuit groups are arranged in one-to-one correspondence, the plurality of first data read lines and the plurality of first signal receiving circuit groups are arranged in one-to-one correspondence,
each of the first read control lines is connected with multiple first read control terminals of multiple signal receiving circuits extending along the first direction in a corresponding one of the second signal receiving circuit groups, and each of the first data read lines is connected with multiple first data output terminals of multiple signal receiving circuits extending along the second direction in a corresponding one of the first signal receiving circuit groups.

3. The fingerprint identification circuit according to claim 1, further comprising:
a plurality of second signal acquisition lines, each of the second signal acquisition lines extending along the first direction, the plurality of second signal acquisition lines arranged along the second direction,
wherein, the acquisition sub-circuit further comprises a second acquisition signal input terminal and a second acquisition signal output terminal, the second acquisition signal output terminal is connected to the first node; the plurality of second signal acquisition lines are arranged in one-to-one correspondence with the plurality of second signal receiving circuit groups; and each of the second signal acquisition lines is connected with multiple second acquisition signal input terminals of multiple signal receiving circuits arranged along the first direction in a corresponding one of the second signal receiving circuit groups.

4. The fingerprint identification circuit according to claim 1, further comprising:
a plurality of second read control lines, each of the second read control lines extending along the second direction, and the plurality of second read control lines arranged along the first direction; and
a plurality of second data read lines, each of the second data read lines extending along the first direction, the plurality of second data read lines arranged along the second direction,
wherein the output sub-circuit comprises a second read control terminal and a second data output terminal, the plurality of second read control lines are arranged in one-to-one correspondence with the plurality of first signal receiving circuit groups, the plurality of second data read lines are arranged in one-to-one correspondence with the plurality of second signal receiving circuit groups,
each of the second read control lines is connected with multiple second read control terminals of multiple the signal receiving circuits extending along the second direction in a corresponding one of the first signal receiving circuit groups, and each of the second data read lines is connected with multiple second data output terminals of multiple signal receiving circuits extending along the first direction in a corresponding one of the second signal receiving circuit groups.

5. The fingerprint identification circuit according to claim 1, wherein the acquisition sub-circuit comprises:
a first diode, comprising a first anode and a first cathode,
wherein each of the first signal acquisition lines is connected with the first anode, the first cathode is connected to the first node, the first anode is the first acquisition signal input terminal, and the first cathode is the first acquisition signal output terminal.

6. The fingerprint identification circuit according to claim 1, wherein the acquisition sub-circuit comprises:
a first thin film transistor, comprising a first gate electrode, a first source electrode, and a first drain electrode,
wherein the fingerprint identification circuit further comprises a plurality of first acquisition control lines, each of the first acquisition control lines extends along the second direction, the plurality of first acquisition control lines are arranged along the first direction, the plurality of first acquisition control lines are arranged in one-to-one correspondence with the plurality of first signal receiving circuit groups,
each of the first acquisition control lines is connected with multiple first gate electrodes of multiple signal receiving circuits arranged along the second direction in a corresponding one of the first signal receiving circuit groups, the first source electrode is the first acquisition signal input terminal, and the first drain electrode is the first acquisition signal output terminal.

7. The fingerprint identification circuit according to claim 1, wherein the output sub-circuit comprises:
a second thin film transistor, comprising a second gate electrode, a second source electrode, and a second drain electrode; and
a third thin film transistor, comprising a third gate electrode, a third source electrode, and a third drain electrode,
wherein the second gate electrode is connected to the first node, the second source electrode is configured to be connected with a high voltage source, the second drain electrode is connected to a second node, the third source electrode is connected to the second node, the second gate electrode is the data input terminal, the third gate electrode is the first read control terminal, and the third drain electrode is the first data output terminal.

8. The fingerprint identification circuit according to claim 3, wherein the acquisition sub-circuit further comprises:
a fourth thin film transistor, comprising a fourth gate electrode, a fourth source electrode, and a fourth drain electrode,
wherein the fingerprint identification circuit further comprises a plurality of second acquisition control lines, each of the second acquisition control lines extends along the first direction, the plurality of second acquisition control lines are arranged along the second direction, the plurality of second acquisition control lines are arranged in one-to-one correspondence with the plurality of second signal receiving circuit groups,
each of the second acquisition control lines is connected with multiple fourth gate electrodes of multiple signal receiving circuits arranged along the first direction in a corresponding one of the second signal receiving circuit groups, the fourth source electrode is the second acquisition signal input terminal, and the fourth drain electrode is the second acquisition signal output terminal.

9. The fingerprint identification circuit according to claim 8, wherein the acquisition sub-circuit further comprises:
a second diode, comprising a second anode and a second cathode,
wherein the first drain electrode and the fourth drain electrode are connected with the second anode, and the second cathode is connected to the first node.

10. The fingerprint identification circuit according to claim 4, wherein the output sub-circuit comprises:
a second thin film transistor, comprising a second gate electrode, a second source electrode, and a second drain electrode;
a third thin film transistor, comprising a third gate electrode, a third source electrode, and a third drain electrode; and
a fifth thin film transistor, comprising a fifth gate electrode, a fifth source electrode, and a fifth drain electrode,
wherein the second gate electrode is connected to the first node, the second source electrode is configured to be connected with a high voltage source, the second drain electrode is connected to the second node, the third source electrode is connected to the second node, the second gate electrode is the data input terminal, the third gate electrode is the first read control terminal, the third drain electrode is the first data output terminal,
the fifth source electrode is connected to the second node, the fifth gate electrode is the second read control terminal, and the fifth drain electrode is the second data output terminal.

11. The fingerprint identification circuit according to claim 1, wherein each of the signal receiving circuits further comprises a reset sub-circuit, the reset sub-circuit comprises a sixth thin film transistor,
the sixth thin film transistor comprises a sixth gate electrode, a sixth source electrode, and a sixth drain electrode, the sixth gate electrode is connected with a reset control line, the sixth source electrode is connected with the reset voltage source, and the sixth drain electrode is connected to the first node.

12. A fingerprint identification module, comprising the fingerprint identification circuit according to claim 1.

13. The fingerprint identification module according to claim 12, further comprising:
a plurality of ultrasonic sensors, each of the ultrasonic sensors comprising a transmitting electrode, a receiving electrode, and a piezoelectric material layer located between the transmitting electrode and the receiving electrode,
wherein the plurality of ultrasonic sensors and the plurality of signal receiving circuits are arranged in one-to-one correspondence, and the first node of each of the signal receiving circuits is connected with the receiving electrode of a corresponding one of the ultrasonic sensors.

14. The fingerprint identification module according to claim 13, wherein the plurality of ultrasonic sensors are arranged in an array along the first direction and the second direction to form a plurality of first ultrasonic sensor groups arranged along the first direction and a plurality of second ultrasonic sensor groups arranged along the second direction,
transmitting electrodes of multiple ultrasonic sensors arranged along the second direction in each of the first ultrasonic sensor groups are different, and multiple ultrasonic sensors arranged along the first direction in each of the second ultrasonic sensor groups share one transmitting electrode having a strip shape.

15. A display device, comprising the fingerprint identification module according to claim 12.

16. A driving method of the fingerprint identification circuit according to claim 1, comprising:
dividing the plurality of first signal acquisition lines into N first signal acquisition line groups, each of the first signal acquisition line groups comprising at least two first signal acquisition lines;
after the ultrasonic sensor transmits an ultrasonic wave, according to an arrival time of reflected echo, the at least two first signal acquisition lines in each of the first signal acquisition line groups apply acquisition signals to multiple first acquisition signal input terminals of multiple signal receiving circuits arranged along the second direction in a corresponding one of the first signal receiving circuit groups at different time points to receive the reflected echo; and
performing weighted summation on data output by multiple first data output terminals of the first signal receiving circuit groups corresponding to the at least two first acquisition signal lines to obtain first fingerprint information,
wherein N is a positive integer greater than or equal to 1.

17. The driving method of the fingerprint identification circuit according to claim 16, wherein the fingerprint identification circuit further comprises: a plurality of first read control lines, each of the first read control lines extending along the first direction, and the plurality of first read control lines arranged along the second direction; and a plurality of first data read lines, each of the first data read lines extending along the second direction, the plurality of first data read lines arranged along the first direction, the plurality of first read control lines and the plurality of second signal receiving circuit groups are arranged in one-to-one correspondence, the plurality of first data read lines and the plurality of first signal receiving circuit groups are arranged in one-to-one correspondence, each of the first read control lines is connected with multiple first read control terminals of multiple signal receiving circuits extending along the first direction in a corresponding one of the second signal receiving circuit groups, and each of the first data read lines is connected with multiple first data output terminals of multiple signal receiving circuits extending along the second direction in a corresponding one of the first signal receiving circuit groups, and the driving method further comprises:
after the plurality of first signal acquisition lines send the acquisition signals, applying turn-on signals to the multiple first read control terminals of the multiple signal receiving circuits extending along the first direction in the corresponding one of the second signal receiving circuit groups through the plurality of first read control lines respectively.

18. The driving method of the fingerprint identification circuit according to claim 17, wherein the fingerprint identification driving circuit further comprises a plurality of second signal acquisition lines, each of the second signal acquisition lines extending along the first direction, the plurality of second signal acquisition lines arranged along the second direction, the acquisition sub-circuit further comprises a second acquisition signal input terminal and a second acquisition signal output terminal, the second acquisition signal output terminal is connected to the first node; the plurality of second signal acquisition lines are arranged in one-to-one correspondence with the plurality of second signal receiving circuit groups; and each of the second signal acquisition lines is connected with multiple second acquisition signal input terminals of multiple signal receiving circuits arranged along the first direction in a corresponding one of the second signal receiving circuit groups, the driving method further comprises:
dividing the plurality of second signal acquisition lines into M second signal acquisition line groups, each of the second signal acquisition line groups comprises at least two second signal acquisition lines;
after the ultrasonic sensor transmits an ultrasonic wave, according to an arrival time of reflected echo, the at least two second signal acquisition lines in each of the second signal acquisition line groups apply acquisition signals to the multiple second acquisition signal input terminals of the multiple of signal receiving circuits arranged along the first direction in the corresponding one of the second signal receiving circuit groups at different time points to receive the reflected echo; and
performing weighted summation on data output by the multiple second data output terminals of the second signal receiving circuit groups corresponding to the at least two second acquisition signal lines to obtain second fingerprint information,
wherein M is a positive integer greater than or equal to 1.

19. The driving method of the fingerprint identification circuit according to claim 18, further comprising:
processing the first fingerprint information and the second fingerprint information to obtain third fingerprint information.

20. The driving method of the fingerprint identification circuit according to claim 18, wherein the fingerprint identification circuit further comprises a plurality of second read control lines and a plurality of second data read lines, each of the second read control lines extending along the second direction, and the plurality of second read control lines arranged along the first direction; each of the second data read lines extending along the first direction, the plurality of second data read lines arranged along the second direction, the output sub-circuit comprises a second read control terminal and a second data output terminal, the plurality of second read control lines are arranged in one-to-one correspondence with the plurality of first signal receiving circuit groups, the plurality of second data read lines are arranged in one-to-one correspondence with the plurality of second signal receiving circuit groups, each of the second read control lines is connected with multiple second read control terminals of multiple the signal receiving circuits extending along the second direction in a corresponding one of the first signal receiving circuit groups, and each of the second data read lines is connected with multiple second data output terminals of multiple signal receiving circuits extending along the first direction in a corresponding one of the second signal receiving circuit groups, and the driving method further comprises:
after the plurality of second signal acquisition lines send the acquisition signals, applying turn-on signals to the multiple second read control terminals of the multiple signal receiving circuits extending along the second direction in the corresponding one of the first signal receiving circuit groups through the plurality of second read control lines respectively.
